(19) United States
(12) Patent Application Publication
(10) Pub. No.: US 2015/0325708 A1
(43) Pub. Date: Nov. 12, 2015

(54) SEMICONDUCTOR DEVICE

(71) Applicant: Semiconductor Energy Laboratory Co., Ltd., Atsugi-shi (JP)

(72) Inventors: Yuto YAKUBO, Isehara (JP); Suguru HONDO, Yokohama (JP); Akihisa SHIMOMURA, Atsugi (JP); Shunpei YAMAZAKI, Tokyo (JP); Shuhei NAGATSUKA, Atsugi (JP)

(21) Appl. No.: 14/704,101

(22) Filed: May 5, 2015

(30) Foreign Application Priority Data
May 9, 2014 (JP) 2014-098038
Jun. 23, 2014 (JP) 2014-128281

(51) Int. Cl. H01L 29/786; H01L 29/36; H01L 29/423; H01L 27/06; H01L 27/092; H01L 29/04; H01L 29/10

(52) U.S. Cl. CPC H01L 29/78696; H01L 29/7869; H01L 29/045; H01L 29/36; H01L 29/1033; H01L 27/0629; H01L 27/092; H01L 29/4238

(57) ABSTRACT

A transistor capable of being driven at high operating frequency is provided. The transistor includes first to third oxide semiconductor layers, a gate insulating layer, a gate electrode layer, and a portion in which the first to third oxide semiconductor layers are sequentially stacked. Channel length is less than 100 nm, and cutoff frequency at a source-drain voltage of higher than or equal to 1 V and lower than or equal to 2 V is higher than 1 GHz. The gate insulating layer is in contact with a top surface of the third oxide semiconductor layer. The gate electrode layer partly overlaps with the portion with the gate insulating layer positioned therebetween. The second oxide semiconductor layer includes a plurality of c-axis aligned crystal parts and a region in which the concentration of hydrogen measured by secondary ion mass spectrometry is lower than 2×10²⁰ atoms/cm³.

### BACKGROUND OF THE INVENTION

1. Field of the Invention

The present invention relates to an object, a method, or a manufacturing method. In addition, the present invention relates to a process, a machine, manufacture, or a composition of matter. One embodiment of the present invention relates to a semiconductor device, a display device, a light-emitting device, a power storage device, a storage device, a driving method thereof, or a manufacturing method thereof. In particular, one embodiment of the present invention relates to a semiconductor device, a display device, or a light-emitting device each including an oxide semiconductor.

In this specification and the like, a semiconductor device generally means a device that can function by utilizing semiconductor characteristics. A display device, an electro-optical device, a semiconductor circuit, and an electronic device include a semiconductor device in some cases.

2. Description of the Related Art

A technique in which a transistor is formed using a semiconductor material has attracted attention. The transistor is used in a wide range of electronic devices such as an integrated circuit (IC) or an image display device (also simply referred to as a display device). A silicon-based semiconductor material is widely known as a semiconductor material applicable to the transistor. As another material, an oxide semiconductor has attracted attention.

For example, a technique for forming a transistor using zinc oxide or an In—Ga—Zn-based oxide semiconductor as an oxide semiconductor is disclosed (see Patent Documents 1 and 2).

In recent years, demand for integrated circuits in which semiconductor elements such as downsized transistors are integrated with high density has risen with increased performance and reductions in the size and weight of electronic devices.

### REFERENCE

Patent Document 1: Japanese Published Patent Application No. 2007-123861
Patent Document 2: Japanese Published Patent Application No. 2007-096055

### SUMMARY OF THE INVENTION

It is an object of one embodiment of the present invention to provide a transistor capable of high-speed operation. It is an object of one embodiment of the present invention to provide a semiconductor device capable of high-speed operation. It is an object of one embodiment of the present invention to provide a novel semiconductor device.

Note that the description of a plurality of objects does not disturb the existence of each object. One embodiment of the present invention does not necessarily achieve all the objects described above. Other objects will be apparent from and can be derived from the description of the specification, the drawings, the claims, and the like, and such objects could be objects of one embodiment of the present invention.

One embodiment of the present invention is a transistor that includes first to third oxide semiconductor layers, a gate insulating layer, and a gate electrode layer. The cutoff frequency of the transistor at a source-drain voltage of higher than or equal to 1 V and lower than or equal to 2 V is preferably higher than 1 GHz. Channel length is preferably less than 100 nm. The second oxide semiconductor layer includes a portion between the first oxide semiconductor layer and the third oxide semiconductor layer. The gate insulating layer includes a region in contact with a top surface of the third oxide semiconductor layer. The gate electrode layer partly overlaps with the portion with the gate insulating layer positioned therebetween. The second oxide semiconductor layer includes a plurality of c-axis aligned crystal parts. The second oxide semiconductor layer preferably includes a region in which the concentration of hydrogen measured by secondary ion mass spectrometry is lower than 2×10²⁰ atoms/cm³.

In the above embodiment, the cutoff frequency at the source-drain voltage of higher than or equal to 1 V and lower than or equal to 2 V is preferably higher than 5 GHz.

One embodiment of the present invention is a transistor that includes first to third oxide semiconductor layers, a gate insulating layer, and a gate electrode layer. The maximum oscillation frequency of the transistor at a source-drain voltage of higher than or equal to 1 V and lower than or equal to 2 V is preferably higher than 1 GHz. Channel length is preferably less than 100 nm. The second oxide semiconductor layer includes a portion between the first oxide semiconductor layer and the third oxide semiconductor layer. The gate insulating layer includes a region in contact with a top surface of the third oxide semiconductor layer. The gate electrode layer partly overlaps with the portion with the gate insulating layer positioned therebetween. The second oxide semiconductor layer includes a plurality of c-axis aligned crystal parts. The second oxide semiconductor layer preferably includes a region in which the concentration of hydrogen measured by secondary ion mass spectrometry is lower than 2×10²⁰ atoms/cm³.

In the above embodiment, the maximum oscillation frequency at the source-drain voltage of higher than or equal to 1 V and lower than or equal to 2 V is preferably higher than 5 GHz.

In the above embodiment, the gate electrode layer may overlap with a top surface of the portion and a side surface of the portion in a channel width direction with the gate insulating layer positioned therebetween.

In the above embodiment, the second oxide semiconductor layer preferably includes a region in which the concentration of silicon measured by secondary ion mass spectrometry is lower than 1×10¹⁹ atoms/cm³.

In the above embodiment, channel length of the transistor is preferably less than 65 nm.

In the above embodiment, the first to third oxide semiconductor layers preferably contain indium, zinc, and M (M is Al, Ti, Ga, Y, Zr, La, Ce, Nd, or Hf).

In the above embodiment, an atomic ratio of M to In in each of the first and third oxide semiconductor layers is preferably higher than an atomic ratio of M to In in the second oxide semiconductor layer.

One embodiment of the present invention is a circuit that includes the n-channel transistor in the above embodiment and a capacitor. The capacitor is capable of being charged and discharged by drain current of the n-channel transistor.

One embodiment of the present invention is an inverter circuit that includes the n-channel transistor in the above embodiment and a p-channel transistor.

One embodiment of the present invention is an electronic component that includes a circuit portion including one of the circuit in the above embodiment and the inverter circuit in the above embodiment and a wire electrically connected to the circuit portion.

One embodiment of the present invention is an electronic device that includes the electronic component in the above embodiment and at least one of a microphone, a speaker, a display portion, and an operation key.

One embodiment of the present invention can provide a transistor capable of high-speed operation. One embodiment of the present invention can provide a semiconductor device capable of high-speed operation. One embodiment of the present invention can provide a novel semiconductor device.

Note that the description of these effects does not disturb the existence of other effects. In one embodiment of the present invention, there is no need to obtain all the effects described above. Other effects will be apparent from and can be derived from the description of the specification, the drawings, the claims, and the like.

### BRIEF DESCRIPTION OF THE DRAWINGS

In the accompanying drawings:

FIGS. 1A to 1D are a top view and cross-sectional views illustrating a transistor structure example;

FIG. 2A is a cross-sectional view illustrating a transistor structure example, and FIG. 2B is a band diagram of the transistor;

FIGS. 3A to 3D are a top view and cross-sectional views illustrating a transistor structure example;

FIGS. 4A to 4D are a top view and cross-sectional views illustrating a transistor structure example;

FIGS. 5A to 5D are a top view and cross-sectional views illustrating a transistor structure example;

FIGS. 6A to 6D are a top view and cross-sectional views illustrating a transistor structure example;

FIGS. 7A to 7D are a top view and cross-sectional views illustrating a transistor structure example;

FIGS. 8A to 8J are circuit diagrams each illustrating a semiconductor device example;

FIGS. 9A to 9C are a cross-sectional view and circuit diagrams illustrating a semiconductor device structure example;

FIGS. 10A and 10B are cross-sectional views illustrating a semiconductor device structure example;

FIG. 11 is a circuit diagram illustrating a semiconductor device example;

FIGS. 12A to 12F illustrate electronic device examples;

FIGS. 13A to 13F illustrate RF tag examples;

FIGS. 14A and 14B show XRD evaluation results of oxide semiconductor films;

FIGS. 15A and 15B show V_{G}-I_{D} characteristics of fabricated transistors;

FIG. 16 is a top view of a fabricated TEG;

FIG. 17 is a top view of a fabricated TEG;

FIG. 18 is a top view of a fabricated TEG;

FIG. 19 shows an H-matrix element and a maximum unilateral power gain of a fabricated transistor;

FIG. 20 shows cutoff frequencies of fabricated transistors;

FIG. 21 shows maximum oscillation frequencies of fabricated transistors;

FIGS. 22A and 22B show V_{D}-I_{D} characteristics of fabricated transistors;

FIG. 23 shows measurement results of transconductance of fabricated transistors;

FIG. 24 shows measurement results of cutoff frequencies and maximum oscillation frequencies of fabricated transistors;

FIGS. 25A and 25B show a fabricated transistor structure;

FIGS. 26A to 26D are Cs-corrected high-resolution TEM images of a cross section of a CAAC-OS and a cross-sectional schematic view of the CAAC-OS;

FIGS. 27A to 27D are Cs-corrected high-resolution TEM images of a plane of a CAAC-OS;

FIGS. 28A to 28C show structural analysis of a CAAC-OS and a single crystal oxide semiconductor by XRD;

FIGS. 29A and 29B show electron diffraction patterns of a CAAC-OS;

FIG. 30 shows a change in crystal part of an In—Ga—Zn oxide induced by electron irradiation; and

FIG. 31 is a triangular diagram showing composition of an In-M-Zn oxide.

### DETAILED DESCRIPTION OF THE INVENTION

Embodiments will be described in detail with reference to the drawings. Note that the present invention is not limited to the following description. It will be readily appreciated by those skilled in the art that modes and details of the present invention can be modified in various ways without departing from the spirit and scope of the present invention. The present invention therefore should not be construed as being limited to the following description of the embodiments.

Note that in the structures of the invention described below, the same portions or portions having similar functions are denoted by the same reference numerals in different drawings, and description of such portions is not repeated. In some cases, the same hatching pattern is used for portions having similar functions, and the portions are not denoted by reference numerals.

Note that in each drawing described in this specification, the size, the layer thickness, or the region of each component is exaggerated for clarity in some cases. Therefore, embodiments of the present invention are not limited to such scales.

In this specification and the like, ordinal numbers such as “first” and “second” are used to avoid confusion among components, and thus do not limit the number of the components.

Note that a “semiconductor” includes characteristics of an “insulator” in some cases when conductivity is sufficiently low, for example. Furthermore, a “semiconductor” and an “insulator” cannot be strictly distinguished from each other in some cases because a border between the “semiconductor” and the “insulator” is not clear. Accordingly, a “semiconductor” in this specification can be called an “insulator” in some cases. Similarly, an “insulator” in this specification can be called a “semiconductor” in some cases.

A transistor is a kind of semiconductor elements and can achieve amplification of current or voltage, switching operation for controlling conduction or non-conduction, or the like. A transistor in this specification includes an insulated-gate field effect transistor (IGFET) and a thin film transistor (TFT).

Note that the terms “film” and “layer” can be interchanged with each other according to circumstances. For example, the term “conductive layer” can be changed into the term “conductive film” in some cases. In addition, the term “insulating film” can be changed into the term “insulating layer” in some cases.

### Embodiment 1

In this embodiment, an example of a transistor which is one embodiment of the present invention is described.

### <Structure Example 1 of Transistor>

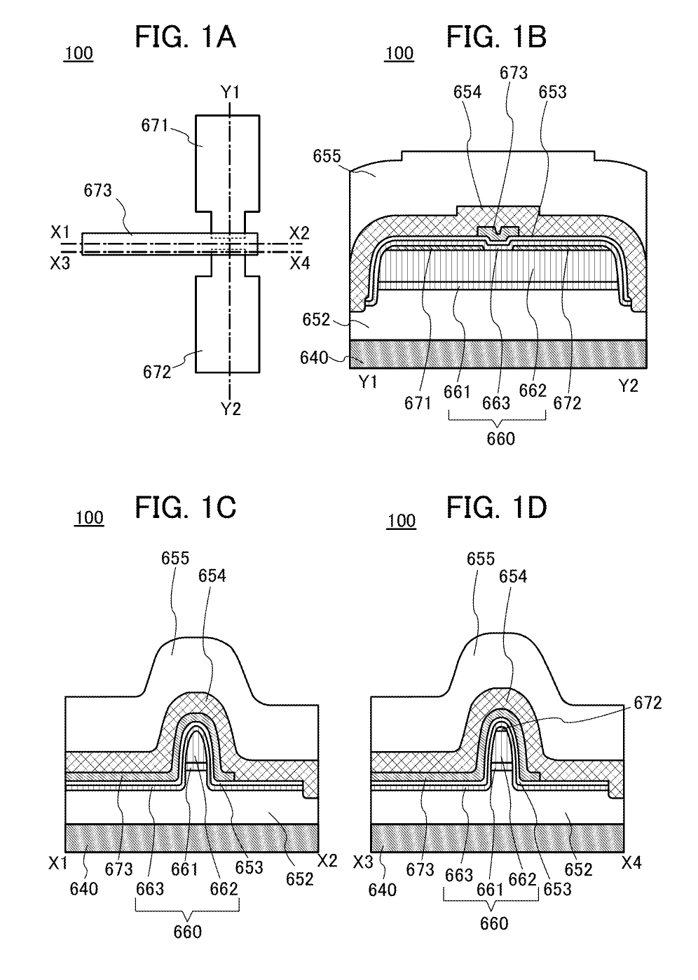

FIGS. 1A to 1D are a top view and cross-sectional views illustrating a transistor 100. FIG. 1A is the top view. FIG. 1B illustrates a cross section taken along dashed-dotted line Y1-Y2 in FIG. 1A. FIG. 1C illustrates a cross section taken along dashed-dotted line X1-X2 in FIG. 1A. FIG. 1D illustrates a cross section taken along dashed-dotted line X3-X4 in FIG. 1A. In FIGS. 1A to 1D, some components are scaled up or down or omitted for easy understanding. In some cases, the direction of dashed-dotted line Y1-Y2 is referred to as a channel length direction and the direction of dashed-dotted line X1-X2 is referred to as a channel width direction.

Note that the channel length refers to, for example, a distance between a source (a source region or a source electrode) and a drain (a drain region or a drain electrode) in a region where a semiconductor (or a portion where current flows in a semiconductor when a transistor is on) and a gate electrode overlap with each other or in a region where a channel is formed in a top view of the transistor. In one transistor, channel lengths in all regions are not necessarily the same. In other words, the channel length of one transistor is not limited to one value in some cases. Therefore, in this specification, the channel length is any one of values, the maximum value, the minimum value, or the average value in a region where a channel is formed.

The channel width refers to, for example, the length of a portion where a source and a drain face each other in a region where a semiconductor (or a portion where current flows in a semiconductor when a transistor is on) and a gate electrode overlap with each other or a region where a channel is formed. In one transistor, channel widths in all regions do not necessarily have the same value. In other words, the channel width of one transistor is not fixed to one value in some cases. Therefore, in this specification, the channel width is any one of values, the maximum value, the minimum value, or the average value in a region where a channel is formed.

Note that depending on transistor structures, a channel width in a region where a channel is actually formed (hereinafter referred to as an effective channel width) is sometimes different from a channel width shown in a top view of a transistor (hereinafter referred to as an apparent channel width). For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is higher than the proportion of a channel region formed in a top surface of a semiconductor in some cases. In that case, an effective channel width obtained when a channel is actually formed is greater than an apparent channel width shown in the top view.

In a transistor having a three-dimensional structure, measuring an effective channel width is difficult in some cases. For example, to estimate an effective channel width from a design value, it is necessary to assume that the shape of a semiconductor is known. Therefore, in the case where the shape of a semiconductor is not known accurately, measuring an effective channel width accurately is difficult.

Accordingly, in this specification, in a top view of a transistor, an apparent channel width that is the length of a portion where a source and a drain face each other in a region where a semiconductor and a gate electrode overlap with each other is referred to as a surrounded channel width (SCW) in some cases. Furthermore, in this specification, the term “channel width” may denote a surrounded channel width, i.e., an apparent channel width or an effective channel width. Note that the values of a channel length, a channel width, an effective channel width, an apparent channel width, a surrounded channel width, and the like can be determined by obtaining and analyzing a cross-sectional TEM image and the like.

A surrounded channel width may be used to calculate field-effect mobility, a current value per channel width, and the like of a transistor. In this case, the obtained value is sometimes different from the value obtained by using an effective channel width for the calculation.

The transistor 100 includes a substrate 640; an insulating film 652 over the substrate 640; a layer in which semiconductors 661 and 662 are sequentially stacked over the insulating film 652; conductive films 671 and 672 in contact with a top surface of the semiconductor 662; a semiconductor 663 in contact with the semiconductors 661 and 662 and the conductive films 671 and 672; an insulating film 653 and a conductive film 673 over the semiconductor 663; an insulating film 654 over the conductive film 673 and the insulating film 653; and an insulating film 655 over the insulating film 654. Note that the semiconductors 661 to 663 are collectively referred to as a semiconductor 660.

The conductive film 671 functions as a source electrode of the transistor 100. The conductive film 672 functions as a drain electrode of the transistor 100. Note that functions of a “source” and a “drain” of a transistor are sometimes interchanged with each other when a transistor of an opposite conductivity type is used or when the direction of current flow is changed in circuit operation, for example. Therefore, the terms “source” and “drain” can be interchanged with each other in this specification.

The conductive film 673 functions as a gate electrode of the transistor 100.

The insulating film 653 functions as a gate insulating film of the transistor 100.

As illustrated in FIG. 1C, a side surface of the semiconductor 662 is surrounded by the conductive film 673. With such a structure, the semiconductor 662 can be electrically surrounded by an electric field of the conductive film 673 (a structure in which a semiconductor is electrically surrounded by an electric field of a conductive film (gate electrode) is referred to as a surrounded channel (s-channel) structure). Therefore, a channel is formed in the entire semiconductor 662 (bulk) in some cases. In the s-channel structure, a large amount of current can flow between a source and a drain of a transistor, so that high current in an on state (on-state current) can be achieved. The s-channel structure enables a transistor to operate at high frequency.

Since high on-state current can be obtained, the s-channel structure is suitable for a downsized transistor. A semiconductor device including the downsized transistor can have a high integration degree and high density. For example, the channel length of the transistor is preferably less than or equal to 100 nm, more preferably less than or equal to 60 nm, still more preferably less than or equal to 30 nm, and the channel width of the transistor is preferably less than or equal to 100 nm, more preferably less than or equal to 60 nm, still more preferably less than or equal to 30 nm.

Since high on-state current can be obtained, the s-channel structure is suitable for a transistor that needs to operate at high frequency. A semiconductor device including the transistor can operate at high frequency.

Components of the semiconductor device of this embodiment are described in detail below.

### <Substrate>

As the substrate 640, an insulator substrate, a semiconductor substrate, or a conductor substrate may be used, for example. As the insulator substrate, a glass substrate, a quartz substrate, a sapphire substrate, a stabilized zirconia substrate (e.g., an yttria-stabilized zirconia substrate), or a resin substrate can be used, for example. As the semiconductor substrate, a semiconductor substrate of silicon, germanium, or the like, or a compound semiconductor substrate of silicon carbide, silicon germanium, gallium arsenide, indium phosphide, zinc oxide, or gallium oxide can be used, for example. A semiconductor substrate in which an insulator region is provided in the above semiconductor substrate, e.g., a silicon on insulator (SOI) substrate can be used. As the conductor substrate, a graphite substrate, a metal substrate, an alloy substrate, a conductive resin substrate, or the like can be used. A substrate including a metal nitride, a substrate including a metal oxide, or the like can be used. An insulator substrate provided with a conductor or a semiconductor, a semiconductor substrate provided with a conductor or an insulator, a conductor substrate provided with a semiconductor or an insulator, or the like can be used. Alternatively, any of these substrates over which an element is provided may be used. As the element provided over the substrate, a capacitor, a resistor, a switching element, a light-emitting element, a memory element, or the like can be used.

A flexible substrate may be used as the substrate 640. As a method for providing a transistor over a flexible substrate, there is a method in which a transistor is formed over a non-flexible substrate, and then the transistor is separated and transferred to the substrate 640 that is a flexible substrate. In that case, a separation layer is preferably provided between the non-flexible substrate and the transistor. As the substrate 640, a sheet, a film, or foil containing a fiber may be used. The substrate 640 may have elasticity. The substrate 640 may have a property of returning to its original shape when bending or pulling is stopped. Alternatively, the substrate 640 may have a property of not returning to its original shape. The thickness of the substrate 640 is, for example, greater than or equal to 5 μm and less than or equal to 700 μm, preferably greater than or equal to 10 μm and less than or equal to 500 μm, more preferably greater than or equal to 15 μm and less than or equal to 300 μm. When the substrate 640 has small thickness, the weight of the semiconductor device can be reduced. When the substrate 640 has small thickness, even in the case of using glass or the like, the substrate 640 may have elasticity or a property of returning to its original shape when bending or pulling is stopped. Therefore, an impact applied to the semiconductor device over the substrate 640, which is caused by dropping or the like, can be reduced. That is, a durable semiconductor device can be provided.

For the flexible substrate 640, metal, an alloy, resin, glass, or fiber thereof can be used, for example. The flexible substrate 640 preferably has a lower coefficient of linear expansion because deformation due to an environment is suppressed. The flexible substrate 640 is formed using, for example, a material whose coefficient of linear expansion is lower than or equal to 1×10⁻³/K, lower than or equal to 5×10⁻⁵/K, or lower than or equal to 1×10⁻⁵/K. Examples of the resin include polyester, polyolefin, polyamide (e.g., nylon or aramid), polyimide, polycarbonate, and acrylic. In particular, aramid is preferably used for the flexible substrate 640 because of its low coefficient of linear expansion.

### <Base Insulating Film>

It is preferable that the top surface of the insulating film 652 be planarized by chemical mechanical polishing (CMP) or the like.

The insulating film 652 preferably contains an oxide. In particular, the insulating film 652 preferably contains an oxide material from which part of oxygen is released by heating. The insulating film 652 preferably contains an oxide containing oxygen more than that in the stoichiometric composition. Part of oxygen is released by heating from an oxide film containing oxygen more than that in the stoichiometric composition. Oxygen released from the insulating film 652 is supplied to the semiconductor 660 that is an oxide semiconductor, so that oxygen vacancies in the oxide semiconductor can be reduced. Consequently, changes in the electrical characteristics of the transistor can be reduced and the reliability of the transistor can be improved.

The oxide film containing oxygen more than that in the stoichiometric composition is an oxide film of which the amount of released oxygen converted into oxygen atoms is greater than or equal to 1.0×10¹⁸ atoms/cm³, preferably greater than or equal to 3.0×10²⁰ atoms/cm³ in thermal desorption spectroscopy (TDS) analysis. Note that the temperature of the film surface in the TDS analysis is preferably higher than or equal to 100° C. and lower than or equal to 700° C., or higher than or equal to 100° C. and lower than or equal to 500° C.

For example, as such a material, a material containing silicon oxide or silicon oxynitride is preferably used. Alternatively, a metal oxide can be used. As the metal oxide, aluminum oxide, aluminum oxynitride, gallium oxide, gallium oxynitride, yttrium oxide, yttrium oxynitride, hafnium oxide, hafnium oxynitride, or the like can be used. Note that in this specification, silicon oxynitride refers to a material that contains more oxygen than nitrogen, and silicon nitride oxide refers to a material that contains more nitrogen than oxygen.

In order that the insulating film 652 contains excess oxygen, a region containing excess oxygen may be formed by introduction of oxygen into the insulating film 652. For example, oxygen (including at least one of an oxygen radical, an oxygen atom, and an oxygen ion) is introduced into the insulating film 652 that has been formed, so that a region containing excess oxygen is formed. Oxygen can be introduced by ion implantation, ion doping, plasma immersion ion implantation, plasma treatment, or the like.

### <Semiconductor>

Next, an oxide semiconductor that can be used as the semiconductor 661, the semiconductor 662, the semiconductor 663, or the like is described.

As the transistor 100, a transistor having low current that flows between a source and a drain in an off state (low off-state current) is preferably used. Here, low off-state current means that normalized off-state current per micrometer of channel width at room temperature with a source-drain voltage of 10 V is lower than or equal to 10×10⁻²¹ A. An example of a transistor with such low off-state current is a transistor including an oxide semiconductor as a semiconductor.

The semiconductor 662 is an oxide semiconductor containing indium (In), for example. The semiconductor 662 can have high carrier mobility (electron mobility) by containing indium, for example. The semiconductor 662 preferably contains an element M. The element M is preferably aluminum (Al), gallium (Ga), yttrium (Y), tin (Sn), or the like. Other elements that can be used as the element M are boron (B), silicon (Si), titanium (Ti), iron (Fe), nickel (Ni), germanium (Ge), yttrium (Y), zirconium (Zr), molybdenum (Mo), lanthanum (La), cerium (Ce), neodymium (Nd), hafnium (Hf), tantalum (Ta), tungsten (W), and the like. Note that two or more of these elements may be used in combination as the element M. The element M is an element having high bonding energy with oxygen, for example. The element M is an element whose bonding energy with oxygen is higher than that of indium, for example. The element M is an element that can increase the energy gap of the oxide semiconductor, for example. Furthermore, the semiconductor 662 preferably contains zinc (Zn). When the oxide semiconductor contains zinc, the oxide semiconductor is easily to be crystallized in some cases.

Note that the semiconductor 662 is not limited to the oxide semiconductor containing indium. The semiconductor 662 may be, for example, an oxide semiconductor that does not contain indium and contains zinc, such as a zinc tin oxide or a gallium tin oxide, an oxide semiconductor containing gallium, or an oxide semiconductor containing tin.

For the semiconductor 662, an oxide with a wide energy gap is used. The energy gap of the semiconductor 662 is, for example, greater than or equal to 2.5 eV and less than or equal to 4.2 eV, preferably greater than or equal to 2.8 eV and less than or equal to 3.8 eV, more preferably greater than or equal to 3 eV and less than or equal to 3.5 eV.

A CAAC-OS film described later is preferably used for the semiconductor 662.

For example, the semiconductors 661 and 663 include one or more elements other than oxygen included in the semiconductor 662. Since the semiconductors 661 and 663 include one or more elements other than oxygen included in the semiconductor 662, an interface state is less likely to be formed at an interface between the semiconductors 661 and 662 and an interface between the semiconductors 662 and 663.

The semiconductors 661 to 663 preferably include at least indium. In the case of using an In-M-Zn oxide as the semiconductor 661, when the total proportion of In and M is assumed to be 100 atomic %, the proportions of In and M are preferably set to be lower than 50 atomic % and higher than 50 atomic %, respectively, more preferably lower than 25 atomic % and higher than 75 atomic %, respectively. In the case of using an In-M-Zn oxide as the semiconductor 662, when the total proportion of In and M is assumed to be 100 atomic %, the proportions of In and M are preferably set to be higher than 25 atomic % and lower than 75 atomic %, respectively, more preferably higher than 34 atomic % and lower than 66 atomic %, respectively. In the case of using an In-M-Zn oxide as the semiconductor 663, when the total proportion of In and M is assumed to be 100 atomic %, the proportions of In and M are preferably set to be lower than 50 atomic % and higher than 50 atomic %, respectively, more preferably lower than 25 atomic % and higher than 75 atomic %, respectively. The semiconductor 663 may be an oxide that is the same type as that of the semiconductor 661. Note that the semiconductor 661 and/or the semiconductor 663 does not necessarily contain indium in some cases. For example, the semiconductor 661 and/or the semiconductor 663 may be gallium oxide.

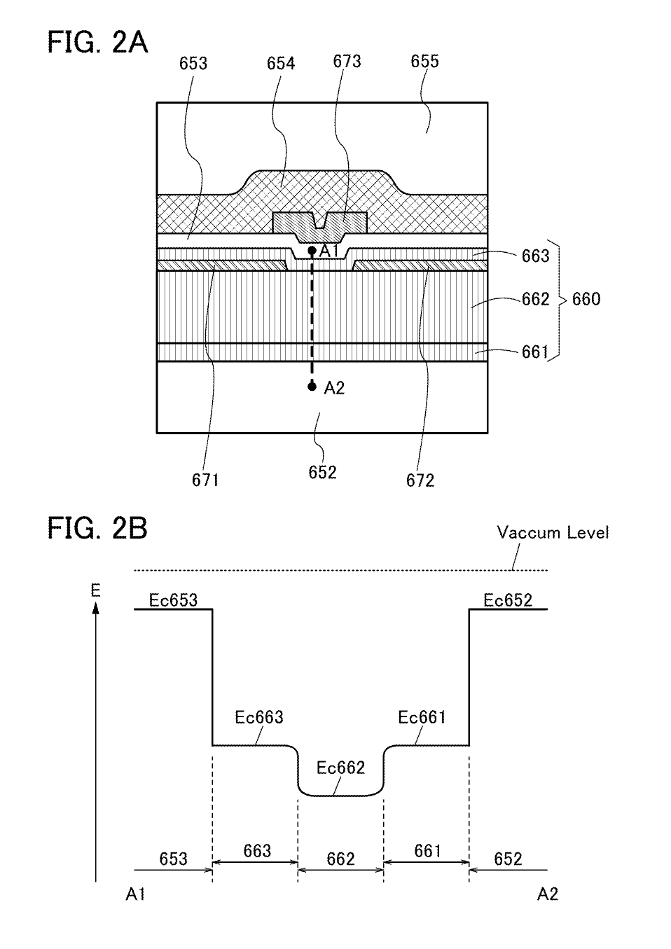

Next, a function and an effect of the semiconductor 660 in which the semiconductors 661 to 663 are stacked are described using an energy band diagram in FIG. 2B. FIG. 2A is an enlarged view of the channel portion of the transistor 100 illustrated in FIG. 1B. FIG. 2B shows the energy band structure of a portion taken along chain line A1-A2 in FIG. 2A. That is, FIG. 2B shows the energy band structure of a channel formation region of the transistor 100.

In FIG. 2B, Ec652, Ec661, Ec662, Ec663, and Ec653 indicate the energy of the conduction band minimum of the insulating film 652, the semiconductor 661, the semiconductor 662, the semiconductor 663, and the insulating film 653, respectively.

Here, a difference in energy between the vacuum level and the conduction band minimum (the difference is also referred to as electron affinity) corresponds to a value obtained by subtracting an energy gap from a difference in energy between the vacuum level and the valence band maximum (the difference is also referred to as ionization potential). The energy gap can be measured using a spectroscopic ellipsometer. The energy difference between the vacuum level and the valence band maximum can be measured using an ultraviolet photoelectron spectroscopy (UPS) device.

Since the insulating films 652 and 653 are insulators, Ec652 and Ec653 are closer to the vacuum level than Ec661 to Ec663 (i.e., the insulating films 652 and 653 have lower electron affinity than the semiconductors 661 to 663).

As the semiconductor 662, an oxide having an electron affinity higher than those of the semiconductors 661 and 663 is used. For example, as the semiconductor 662, an oxide having an electron affinity higher than those of the semiconductors 661 and 663 by greater than or equal to 0.07 eV and less than or equal to 1.3 eV, preferably greater than or equal to 0.1 eV and less than or equal to 0.7 eV, more preferably greater than or equal to 0.15 eV and less than or equal to 0.4 eV is used. Note that electron affinity is an energy gap between the vacuum level and the bottom of the conduction band.

An indium gallium oxide has low electron affinity and a high oxygen-blocking property. Therefore, the semiconductor 663 preferably includes an indium gallium oxide. The gallium atomic ratio [Ga/(In+Ga)] is, for example, higher than or equal to 70%, preferably higher than or equal to 80%, more preferably higher than or equal to 90%.

At this time, when gate voltage is applied, a channel is formed in the semiconductor 662 having the highest electron affinity in the semiconductors 661 to 663.

Here, in some cases, there is a mixed region of the semiconductors 661 and 662 between the semiconductors 661 and 662. Furthermore, in some cases, there is a mixed region of the semiconductors 662 and 663 between the semiconductors 662 and 663. The mixed region has low interface state density. For that reason, the stack of the semiconductors 661 to 663 has a band structure where energy at each interface is changed continuously (continuous junction).

At this time, electrons move mainly in the semiconductor 662, not in the semiconductors 661 and 663. As described above, when the interface state density at the interface between the semiconductors 661 and 662 and the interface state density at the interface between the semiconductors 662 and 663 are decreased, electron movement in the semiconductor 662 is less likely to be inhibited and the on-sate current of the transistor can be increased.

As factors of inhibiting electron movement are decreased, the on-state current of the transistor can be increased. For example, in the case where there is no factor of inhibiting electron movement, electrons are assumed to be moved efficiently. Electron movement is inhibited, for example, in the case where physical unevenness in a channel formation region is large.

To increase the on-state current of the transistor, for example, root mean square (RMS) roughness with a measurement area of 1 μm×1 μm of a top surface or a bottom surface of the semiconductor 662 (a formation surface; here, the semiconductor 661) is less than 1 nm, preferably less than 0.6 nm, more preferably less than 0.5 nm, still more preferably less than 0.4 nm. The average surface roughness (Ra) with the measurement area of 1 μm×1 μm is less than 1 nm, preferably less than 0.6 nm, more preferably less than 0.5 nm, still more preferably less than 0.4 nm. The maximum difference (P-V) with the measurement area of 1 μm×1 μm is less than 10 nm, preferably less than 9 nm, more preferably less than 8 nm, still more preferably less than 7 nm. RMS roughness, Ra, and P-V can be measured using a scanning probe microscope SPA-500 manufactured by SII Nano Technology Inc.

The electron movement is also inhibited, for example, in the case where the density of defect states is high in a region where a channel is formed.

For example, in the case were the semiconductor 662 contains oxygen vacancies (V_{O}), donor levels are formed by entry of hydrogen into sites of oxygen vacancies in some cases. A state in which hydrogen enters sites of oxygen vacancies are denoted by V_{O}H in the following description in some cases. V_{O}H is a factor of decreasing the on-state current of the transistor because V_{O}H scatters electrons. Note that sites of oxygen vacancies become more stable by entry of oxygen than by entry of hydrogen. Thus, by decreasing oxygen vacancies in the semiconductor 662, the on-state current of the transistor can be increased in some cases.

For example, at a certain depth in the semiconductor 662 or in a certain region of the semiconductor 662, the concentration of hydrogen measured by secondary ion mass spectrometry (SIMS) is set to be lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³.

To decrease oxygen vacancies in the semiconductor 662, for example, there is a method in which excess oxygen in the insulating film 652 is moved to the semiconductor 662 through the semiconductor 661. In that case, the semiconductor 661 is preferably a layer having an oxygen-transmitting property (a layer through which oxygen is transmitted).

In the case where the transistor has an s-channel structure, a channel is formed in the entire semiconductor 662. Therefore, as the semiconductor 662 has larger thickness, a channel region becomes larger. In other words, the thicker the semiconductor 662 is, the larger the on-state current of the transistor is. For example, the semiconductor 662 has a region with a thickness of greater than or equal to 20 nm, preferably greater than or equal to 40 nm, more preferably greater than or equal to 60 nm, still more preferably greater than or equal to 100 nm. Note that the semiconductor 662 has a region with a thickness of, for example, less than or equal to 300 nm, preferably less than or equal to 200 nm, more preferably less than or equal to 150 nm because the productivity of the semiconductor device might be decreased.

Moreover, the thickness of the semiconductor 663 is preferably as small as possible to increase the on-state current of the transistor. For example, the semiconductor 663 has a region with a thickness of less than 10 nm, preferably less than or equal to 5 nm, more preferably less than or equal to 3 nm. Meanwhile, the semiconductor 663 has a function of blocking entry of elements other than oxygen (such as hydrogen and silicon) included in the adjacent insulator into the semiconductor 662 where a channel is formed. Thus, the semiconductor 663 preferably has a certain thickness. For example, the semiconductor 663 may have a region with a thickness of greater than or equal to 0.3 nm, preferably greater than or equal to 1 nm, more preferably greater than or equal to 2 nm. The semiconductor 663 preferably has an oxygen blocking property to inhibit outward diffusion of oxygen released from the insulating film 652 and the like.

To improve reliability, preferably, the thickness of the semiconductor 661 is large and the thickness of the semiconductor 663 is small. For example, the semiconductor 661 has a region with a thickness of greater than or equal to 10 nm, preferably greater than or equal to 20 nm, more preferably greater than or equal to 40 nm, still more preferably greater than or equal to 60 nm. When the thickness of the semiconductor 661 is made large, a distance from an interface between the adjacent insulator and the semiconductor 661 to the semiconductor 662 in which a channel is formed can be large. Note that the semiconductor 661 has a region with a thickness of, for example, less than or equal to 200 nm, preferably less than or equal to 120 nm, more preferably less than or equal to 80 nm because the productivity of the semiconductor device might be decreased.

For example, a region in which the concentration of silicon measured by SIMS is lower than 1×10¹⁹ atoms/cm³, preferably lower than 5×10¹⁸ atoms/cm³, more preferably lower than 2×10¹⁸ atoms/cm³ is provided between the semiconductors 661 and 662. A region in which the concentration of silicon measured by SIMS is lower than 1×10¹⁹ atoms/cm³, preferably lower than 5×10¹⁸ atoms/cm³, more preferably lower than 2×10¹⁸ atoms/cm³ is provided between the semiconductors 662 and 663.

It is preferable to reduce the concentration of hydrogen in the semiconductors 661 and 663 in order to reduce the concentration of hydrogen in the semiconductor 662. The semiconductors 661 and 663 each have a region in which the concentration of hydrogen measured by SIMS is lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³. It is preferable to reduce the concentration of nitrogen in the semiconductors 661 and 663 in order to reduce the concentration of nitrogen in the semiconductor 662. The semiconductors 661 and 663 each have a region in which the concentration of nitrogen measured by SIMS is lower than or equal to 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The above three-layer structure is an example. For example, a two-layer structure without the semiconductor 661 or 663 may be employed. A four-layer structure in which any one of the semiconductors described as examples of the semiconductors 661 to 663 is provided below or over the semiconductor 661 or below or over the semiconductor 663 may be employed. An n-layer structure (n is an integer of five or more) in which any one of the semiconductors described as examples of the semiconductors 661 to 663 is provided at two or more of the following positions: over the semiconductor 661, below the semiconductor 661, over the semiconductor 663, and below the semiconductor 663.

When the semiconductors 661 to 663 have the above structures, the transistor 100 can have high on-state current and operate at high frequency.

### <Conductive Film>

The conductive films 671 to 673 preferably have a single-layer structure or a layered structure of a conductive film containing a low-resistance material selected from copper (Cu), tungsten (W), molybdenum (Mo), gold (Au), aluminum (Al), manganese (Mn), titanium (Ti), tantalum (Ta), nickel (Ni), chromium (Cr), lead (Pb), tin (Sn), iron (Fe), cobalt (Co), ruthenium (Ru), platinum (Pt), iridium (Ir), and strontium (Sr); an alloy of such a low-resistance material; or a compound containing such a material as its main component. It is particularly preferable to use a high-melting-point material that has heat resistance and conductivity, such as tungsten or molybdenum. The conductive films 671 to 673 are preferably formed using a low-resistance conductive material such as aluminum or copper. The conductive films 671 to 673 are particularly preferably formed using a Cu—Mn alloy because manganese oxide formed at the interface with an insulator containing oxygen has a function of preventing Cu diffusion.

The conductive films 671 to 673 can also be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. Moreover, the conductive films 671 to 673 can have a layered structure using the light-transmitting conductive material and the metal element.

The conductive films 671 to 673 are preferably formed using a conductive oxide including noble metal, such as iridium oxide, ruthenium oxide, or strontium ruthenate. Such a conductive oxide hardly takes oxygen from an oxide semiconductor even when it is in contact with the oxide semiconductor and hardly generates oxygen vacancies in the oxide semiconductor.

### <Gate Insulating Film>

The insulating film 653 can be formed using an insulating film containing one or more of aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide. The insulating film 653 may be a stack of any of the above materials. Note that the insulating film 653 may contain lanthanum (La), nitrogen, zirconium (Zr), or the like as an impurity.

An example of a layered structure of the insulating film 653 is described. The insulating film 653 contains oxygen, nitrogen, silicon, or hafnium, for example. Specifically, the insulating film 653 preferably contains hafnium oxide and one of silicon oxide and silicon oxynitride.

Hafnium oxide has a higher dielectric constant than silicon oxide and silicon oxynitride. Therefore, by using hafnium oxide, the thickness can be larger than silicon oxide; thus, leakage current due to tunneling current can be low. That is, it is possible to provide a transistor with low off-state current.

### <Protective Insulating Film>

The insulating film 654 has a function of blocking oxygen, hydrogen, water, alkali metal, alkaline earth metal, and the like. The insulating film 654 can prevent outward diffusion of oxygen from the semiconductor 660 and entry of hydrogen, water, or the like into the semiconductor 660 from the outside. The insulating film 654 can be a nitride insulating film, for example. Examples of the nitride insulating film include a silicon nitride film, a silicon nitride oxide film, an aluminum nitride film, and an aluminum nitride oxide film. Note that instead of the nitride insulating film having a blocking effect against oxygen, hydrogen, water, alkali metal, alkaline earth metal, and the like, an oxide insulating film having a blocking effect against oxygen, hydrogen, water, and the like may be provided. Examples of the oxide insulating film having a blocking effect against oxygen, hydrogen, water, and the like include an aluminum oxide film, an aluminum oxynitride film, a gallium oxide film, a gallium oxynitride film, an yttrium oxide film, an yttrium oxynitride film, a hafnium oxide film, and a hafnium oxynitride film.

An aluminum oxide film is preferably used as the insulating film 654 because it is highly effective in preventing transmission of both oxygen and impurities such as hydrogen and moisture. Thus, during and after the manufacturing process of the transistor, the aluminum oxide film can suitably function as a protective film that has effects of preventing entry of impurities such as hydrogen and moisture, which cause variations in the electrical characteristics of the transistor, into the semiconductor 660, preventing release of oxygen, which is the main component of the semiconductor 660, from the oxide semiconductor, and preventing unnecessary release of oxygen from the insulating film 652. Furthermore, oxygen contained in the aluminum oxide film can be diffused into the oxide semiconductor.

### <Interlayer Insulating Film>

The insulating film 655 is preferably formed over the insulating film 654. The insulating film 655 can be formed using an insulator containing one or more materials selected from aluminum oxide, aluminum nitride oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, tantalum oxide, and the like. Alternatively, the insulating film 655 can be formed using an organic resin such as a polyimide resin, a polyamide resin, an acrylic resin, a siloxane resin, an epoxy resin, or a phenol resin. The insulating film 655 may be a stack of any of the above materials.

### <Structure of Oxide Semiconductor Film>

The structure of an oxide semiconductor that can be used as the semiconductor 662 is described below.

In this specification, the term “parallel” indicates that an angle formed between two straight lines is greater than or equal to −10° and less than or equal to 10°, and accordingly includes the case where the angle is greater than or equal to −5° and less than or equal to 5°. The term “substantially parallel” indicates that an angle formed between two straight lines is greater than or equal to −30° and less than or equal to 30°. In addition, the term “perpendicular” indicates that an angle formed between two straight lines is greater than or equal to 80° and less than or equal to 100°, and accordingly includes the case where the angle is greater than or equal to 85° and less than or equal to 95°. The term “substantially perpendicular” indicates that an angle formed between two straight lines is greater than or equal to 60° and less than or equal to 120°.

In this specification, trigonal and rhombohedral crystal systems are included in a hexagonal crystal system.

### <Structure of Oxide Semiconductor>

The structure of an oxide semiconductor is described below.

An oxide semiconductor is classified into a single crystal oxide semiconductor and a non-single-crystal oxide semiconductor. Examples of a non-single-crystal oxide semiconductor include a c-axis aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor is classified into an amorphous oxide semiconductor and a crystalline oxide semiconductor. Examples of a crystalline oxide semiconductor include a single crystal oxide semiconductor, a CAAC-OS, a polycrystalline oxide semiconductor, and an nc-OS.

It is known that an amorphous structure is generally defined as being metastable and unfixed, and being isotropic and having no non-uniform structure. In other words, an amorphous structure has a flexible bond angle and a short-range order but does not have a long-range order.

This means that an inherently stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. Note that an a-like OS has a periodic structure in a microscopic region, but at the same time has a void and thus has an unstable structure. For this reason, an a-like OS has physical properties similar to those of an amorphous oxide semiconductor.

### <CAAC-OS>

First, a CAAC-OS is described.

A CAAC-OS is an oxide semiconductor having a plurality of c-axis aligned crystal parts (also referred to as pellets).

When a combined analysis image (also referred to as a high-resolution TEM image) of a bright-field image and a diffraction pattern of a CAAC-OS is observed by a transmission electron microscope (TEM), a plurality of pellets can be observed. However, in the high-resolution TEM image, a boundary between pellets, that is, a grain boundary is not clearly observed. Thus, in the CAAC-OS, a reduction in electron mobility due to the grain boundary is less likely to occur.

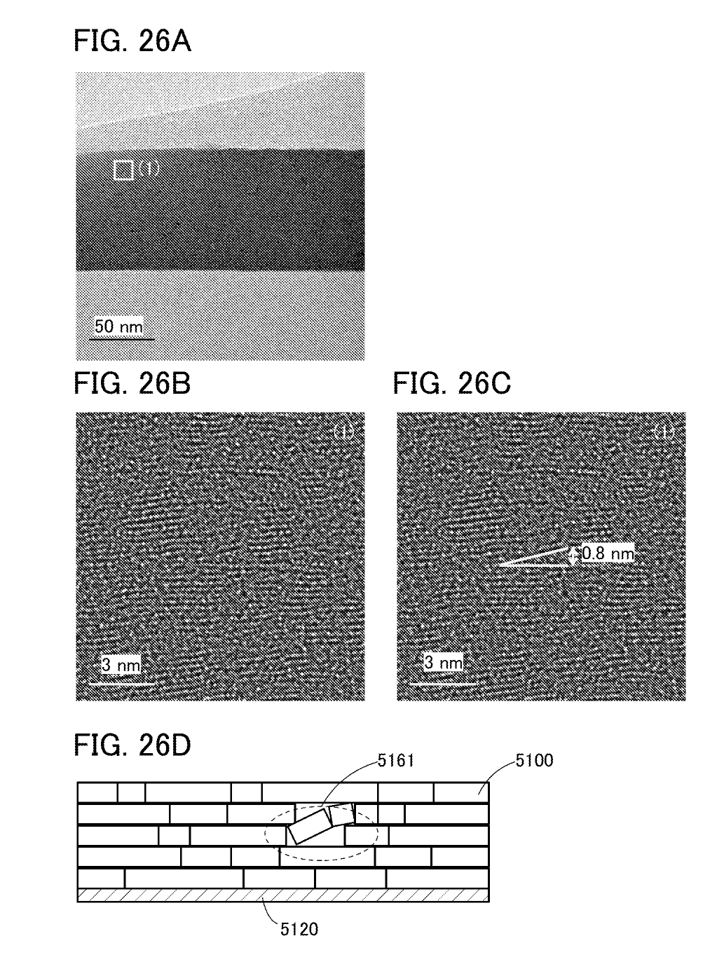

The CAAC-OS observed with a TEM is described below. FIG. 26A shows a high-resolution TEM image of a cross section of the CAAC-OS observed from a direction substantially parallel to a sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be obtained with, for example, an atomic resolution analytical electron microscope JEM-ARM200F manufactured by JEOL Ltd.

FIG. 26B is an enlarged Cs-corrected high-resolution TEM image of a region (1) in FIG. 26A. FIG. 26B shows that metal atoms are arranged in a layered manner in a pellet. Each metal atom layer has a configuration reflecting unevenness of a surface over which a CAAC-OS film is formed (hereinafter the surface is referred to as a formation surface) or a top surface of the CAAC-OS, and is arranged parallel to the formation surface or the top surface of the CAAC-OS.

As shown in FIG. 26B, the CAAC-OS has a characteristic atomic arrangement. The characteristic atomic arrangement is denoted by an auxiliary line in FIG. 26C. FIGS. 26B and 26C prove that the size of a pellet is greater than or equal to 1 nm or greater than or equal to 3 nm, and the size of a space caused by tilt of the pellets is approximately 0.8 nm. Therefore, the pellet can also be referred to as a nanocrystal (nc). The CAAC-OS can be referred to as an oxide semiconductor including c-axis aligned nanocrystals (CANC).

Here, according to the Cs-corrected high-resolution TEM images, the schematic arrangement of pellets 5100 of a CAAC-OS over a substrate 5120 is illustrated by such a structure in which bricks or blocks are stacked (see FIG. 26D). The part in which the pellets are tilted as observed in FIG. 26C corresponds to a region 5161 shown in FIG. 26D.

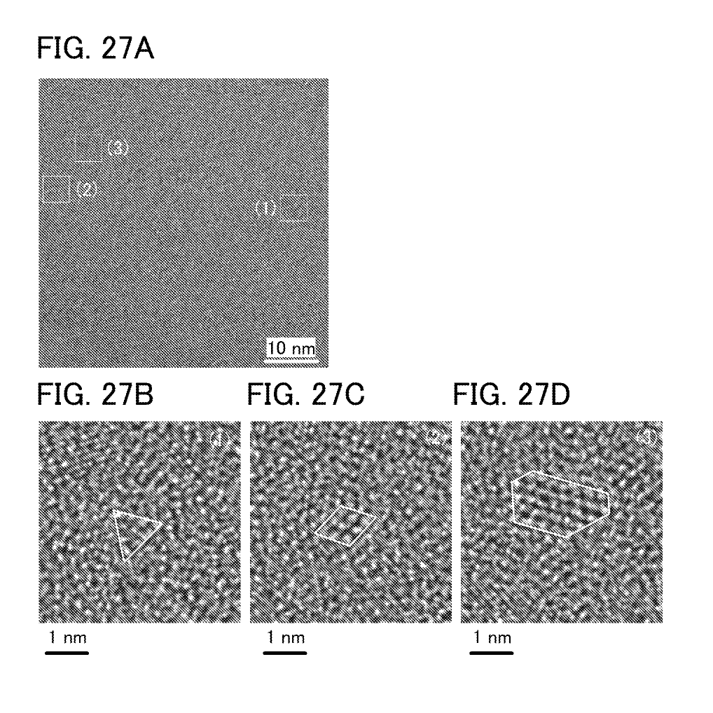

FIG. 27A shows a Cs-corrected high-resolution TEM image of a plane of the CAAC-OS observed from a direction substantially perpendicular to the sample surface. FIGS. 27B, 27C, and 27D are enlarged Cs-corrected high-resolution TEM images of regions (1), (2), and (3) in FIG. 27A, respectively. FIGS. 27B, 27C, and 27D indicate that metal atoms are arranged in a triangular, quadrangular, or hexagonal configuration in a pellet. However, there is no regularity of arrangement of metal atoms between different pellets.

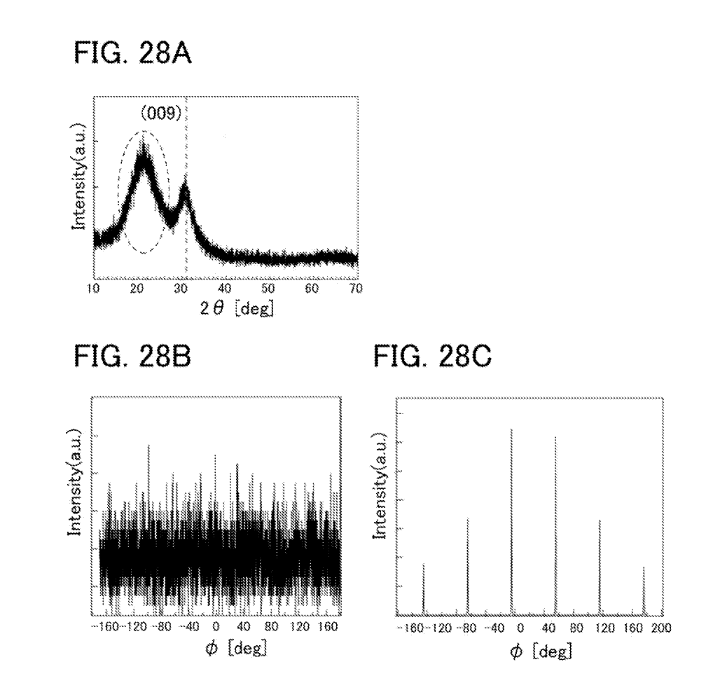

Next, a CAAC-OS analyzed by X-ray diffraction (XRD) is described. For example, when the structure of a CAAC-OS including an InGaZnO₄ crystal is analyzed by an out-of-plane method, a peak appears at a diffraction angle (2θ) of around 31° as shown in FIG. 28A. This peak is derived from the (009) plane of the InGaZnO₄ crystal, which indicates that crystals in the CAAC-OS have c-axis alignment, and that the c-axes are aligned in a direction substantially perpendicular to the formation surface or the top surface of the CAAC-OS.

In structural analysis of the CAAC-OS by an out-of-plane method, another peak might appear when 2θ is around 36°, in addition to the peak at 2θ of around 31°. The peak of 2θ at around 36° indicates that a crystal having no c-axis alignment is included in part of the CAAC-OS. It is preferable that in the CAAC-OS analyzed by an out-of-plane method, a peak appear when 2θ is around 31° and that a peak not appear when 2θ is around 36°.

On the other hand, in structural analysis of the CAAC-OS by an in-plane method in which an X-ray is incident on a sample in a direction substantially perpendicular to the c-axis, a peak appears when 2θ is around 56°. This peak is derived from the (110) plane of the InGaZnO₄ crystal. In the case of the CAAC-OS, when analysis (θ scan) is performed with 2θ fixed at around 56° and with the sample rotated using a normal vector of the sample surface as an axis (θ axis), as shown in FIG. 28B, a peak is not clearly observed. In contrast, in the case of a single crystal oxide semiconductor of InGaZnO₄, when θ scan is performed with 2θ fixed at around 56°, as shown in FIG. 28C, six peaks which are derived from crystal planes equivalent to the (110) plane are observed. Accordingly, the structural analysis using XRD shows that the directions of a-axes and b-axes are irregularly oriented in the CAAC-OS.

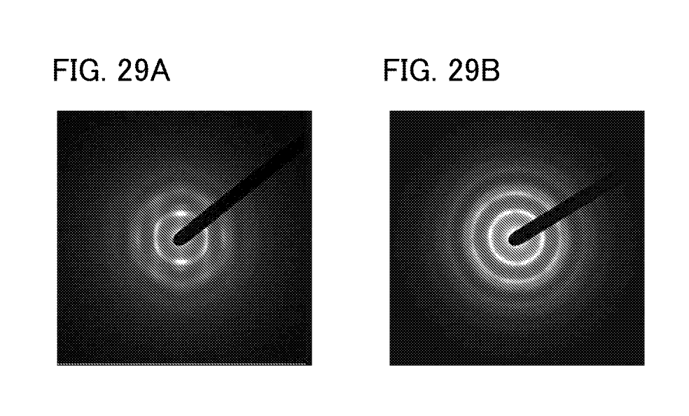

Next, a CAAC-OS analyzed by electron diffraction is described. For example, when an electron beam with a probe diameter of 300 nm is incident on a CAAC-OS including an InGaZnO₄ crystal in the direction parallel to the sample surface, a diffraction pattern (also referred to as a selected-area transmission electron diffraction pattern) shown in FIG. 29A can be obtained. In this diffraction pattern, spots derived from the (009) plane of an InGaZnO₄ crystal are included. Thus, the electron diffraction also indicates that pellets included in the CAAC-OS have c-axis alignment and that the c-axes are aligned in a direction substantially perpendicular to the formation surface or the top surface of the CAAC-OS. Meanwhile, FIG. 29B shows a diffraction pattern obtained in such a manner that an electron beam with a probe diameter of 300 nm is incident on the same sample in a direction perpendicular to the sample surface. As shown in FIG. 29B, a ring-like diffraction pattern is observed. Thus, the electron diffraction also indicates that the a-axes and b-axes of the pellets included in the CAAC-OS do not have regular alignment. A first ring in FIG. 29B is considered to be derived from the (010) plane, the (100) plane, and the like of the InGaZnO₄ crystal. A second ring in FIG. 29B is considered to be derived from the (110) plane and the like.

As described above, the CAAC-OS is an oxide semiconductor with high crystallinity. Entry of impurities, formation of defects, or the like might decrease the crystallinity of an oxide semiconductor. This means that the CAAC-OS has small amounts of impurities and defects (e.g., oxygen vacancies).

Note that the impurity means an element other than the main components of the oxide semiconductor, such as hydrogen, carbon, silicon, or a transition metal element. For example, an element (e.g., silicon) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

The characteristics of an oxide semiconductor having impurities or defects might be changed by light, heat, or the like. Impurities contained in the oxide semiconductor might serve as carrier traps or carrier generation sources, for example. Furthermore, oxygen vacancies in the oxide semiconductor serve as carrier traps or serve as carrier generation sources when hydrogen is captured therein.

The CAAC-OS having small amounts of impurities and oxygen vacancies is an oxide semiconductor with low carrier density (specifically, lower than 8×10¹¹/cm³, preferably lower than 1×10¹¹/cm³, more preferably lower than 1×10¹⁰/cm³, and is higher than or equal to 1×10⁻⁹/cm³). Such an oxide semiconductor is referred to as a highly purified intrinsic or substantially highly purified intrinsic oxide semiconductor. A CAAC-OS has a low impurity concentration and a low density of defect states. That is, the CAAC-OS can be referred to as an oxide semiconductor having stable characteristics.

### <Nc-OS>

Next, an nc-OS is described.

An nc-OS has a region in which a crystal part is observed and a region in which a crystal part is not observed clearly in a high-resolution TEM image. In most cases, a crystal part in the nc-OS is greater than or equal to 1 nm and less than or equal to 100 nm, or greater than or equal to 1 nm and less than or equal to 3 nm. Note that an oxide semiconductor including a crystal part whose size is greater than 10 nm and less than or equal to 100 nm is sometimes referred to as a microcrystalline oxide semiconductor. In a high-resolution TEM image of the nc-OS, a grain boundary cannot be found clearly in some cases. There is a possibility that the origin of the nanocrystal is the same as that of a pellet in a CAAC-OS. Therefore, a crystal part of the nc-OS is sometimes referred to as a pellet in the following description.

In the nc-OS, a microscopic region (e.g., a region with a size greater than or equal to 1 nm and less than or equal to 10 nm, in particular, a region with a size greater than or equal to 1 nm and less than or equal to 3 nm) has periodic atomic arrangement. There is no regularity of crystal orientation between different pellets in the nc-OS. Thus, the orientation of the whole film is not observed. Accordingly, in some cases, the nc-OS cannot be distinguished from an a-like OS or an amorphous oxide semiconductor depending on an analysis method. For example, when the nc-OS is analyzed by an out-of-plane method using an X-ray having a diameter larger than that of a pellet, a peak that shows a crystal plane does not appear. Furthermore, a halo pattern is shown in an electron diffraction pattern of the nc-OS obtained by using an electron beam having a probe diameter larger than the diameter of a pellet (e.g., larger than or equal to 50 nm). Meanwhile, spots are shown in a nanobeam electron diffraction pattern of the nc-OS obtained by using an electron beam having a probe diameter close to or smaller than the diameter of a pellet. Furthermore, in a nanobeam electron diffraction pattern of the nc-OS, regions with high luminance in a circular (ring) pattern are observed in some cases. Moreover, a plurality of spots are shown in a ring-like region in some cases.

Since there is no regularity of crystal orientation between the pellets (nanocrystals) as mentioned above, the nc-OS can also be referred to as an oxide semiconductor including random aligned nanocrystals (RANC) or an oxide semiconductor including non-aligned nanocrystals (NANC).

The nc-OS is an oxide semiconductor that has high regularity than an amorphous oxide semiconductor. Thus, the nc-OS has a lower density of defect states than the a-like OS and the amorphous oxide semiconductor. Note that there is no regularity of crystal orientation between different pellets in the nc-OS; thus, the nc-OS has a higher density of defect states than the CAAC-OS.

### <A-Like OS>

An a-like OS is an oxide semiconductor having a structure between the nc-OS and the amorphous oxide semiconductor.

In a high-resolution TEM image of the a-like OS, a void may be seen. Furthermore, in the high-resolution TEM image, there are a region where a crystal part is clearly observed and a region where a crystal part is not observed.

The a-like OS has an unstable structure because it contains a void. To verify that an a-like OS has an unstable structure as compared with a CAAC-OS and an nc-OS, a change in crystal structure caused by electron irradiation is described below.

Three samples of an a-like OS, an nc-OS, and a CAAC-OS are prepared and subjected to electron irradiation. Each of the samples is an In—Ga—Zn oxide.

The crystal structure of each of the samples is obtained from a high-resolution cross-sectional TEM image. Each of the samples includes a crystal part.

Note that which part is regarded as a crystal part is determined as follows. It is known that a unit cell of the InGaZnO₄ crystal has a structure in which nine layers including three In—O layers and six Ga—Zn—O layers are stacked in the c-axis direction. The distance between the adjacent layers is equivalent to the lattice spacing on the (009) plane (also referred to as a d value). The value is calculated to be 0.29 nm from crystal structural analysis. Accordingly, a portion where the lattice spacing between lattice fringes is greater than or equal to 0.28 nm and less than or equal to 0.30 nm is regarded as a crystal part of InGaZnO₄. Each of lattice fringes corresponds to the a-b plane of the InGaZnO₄ crystal.

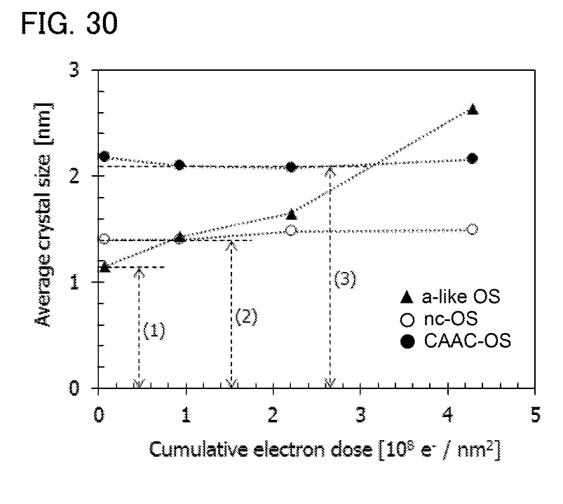

FIG. 30 shows a change in the average size of crystal parts (at 22 to 45 points) in each sample. Note that the crystal part size corresponds to the length of the lattice fringe. FIG. 30 indicates that the crystal part size in the a-like OS increases with an increase in the cumulative electron dose. Specifically, as shown by (1) in FIG. 30, a crystal part of approximately 1.2 nm (also referred to as an initial nucleus) at the start of TEM observation grows to a size of approximately 2.6 nm at a cumulative electron dose of 4.2×10⁸ e⁻/nm². In contrast, the crystal part sizes in the nc-OS and the CAAC-OS show little change from the start of electron irradiation to a cumulative electron dose of 4.2×10⁸ e⁻/nm². Specifically, as shown by (2) and (3) in FIG. 30, the crystal part sizes in the nc-OS and the CAAC-OS are approximately 1.4 nm and approximately 2.1 nm, respectively, regardless of the cumulative electron dose.

In this manner, growth of the crystal part in the a-like OS is induced by electron irradiation. In contrast, in the nc-OS and the CAAC-OS, growth of the crystal part is hardly induced by electron irradiation. Therefore, the a-like OS has an unstable structure as compared with the nc-OS and the CAAC-OS.

The a-like OS has lower density than the nc-OS and the CAAC-OS because it contains a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. It is difficult to deposit an oxide semiconductor whose density is lower than 78% of the density of the single crystal oxide semiconductor.

For example, in the case of an oxide semiconductor with an atomic ratio of In:Ga:Zn=1:1:1, the density of single-crystal InGaZnO₄ with a rhombohedral crystal structure is 6.357 g/cm³. Thus, for example, in the case of the oxide semiconductor with an atomic ratio of In:Ga:Zn=1:1:1, the density of an a-like OS is higher than or equal to 5.0 g/cm³ and lower than 5.9 g/cm³. In addition, for example, in the case of the oxide semiconductor with an atomic ratio of In:Ga:Zn=1:1:1, the density of an nc-OS or a CAAC-OS is higher than or equal to 5.9 g/cm³ and lower than 6.3 g/cm³.

Note that single crystals with the same composition do not exist in some cases. In such a case, by combining single crystals with different compositions at a given proportion, it is possible to estimate density that corresponds to the density of a single crystal with a desired composition. The density of the single crystal with a desired composition may be estimated using weighted average with respect to the combination ratio of the single crystals with different compositions. Note that it is preferable to combine as few kinds of single crystals as possible for density estimation.

As described above, oxide semiconductors have various structures and various properties. An oxide semiconductor may be a stacked film including two or more of an amorphous oxide semiconductor, an a-like OS, an nc-OS, and a CAAC-OS, for example.

Composition of a CAAC-OS is described below. For explanation of the composition, an In-M-Zn oxide that is an oxide semiconductor to be a CAAC-OS is described as an example. The element M is aluminum, gallium, yttrium, tin, or the like. Other elements that can be used as the element M are boron, silicon, titanium, iron, nickel, germanium, yttrium, zirconium, molybdenum, lanthanum, cerium, neodymium, hafnium, tantalum, tungsten, and the like.

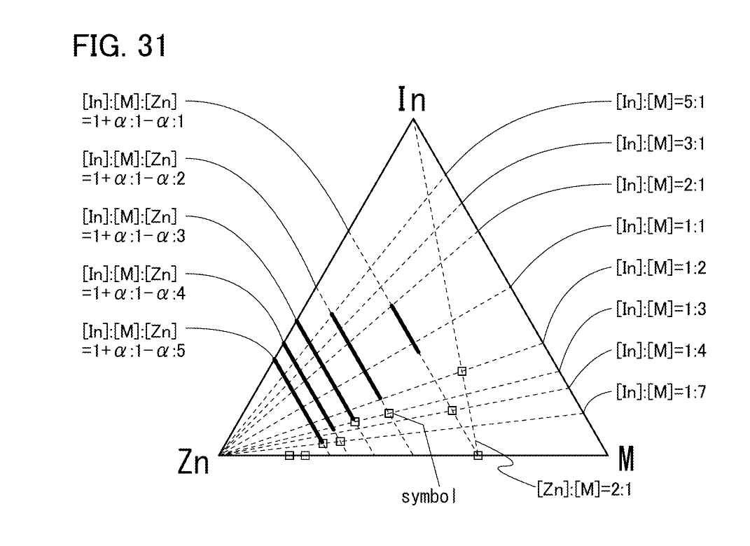

FIG. 31 is a triangular diagram in which the vertices represent In, M, and Zn. In the diagram, [In] means the atomic concentration of In, [M] means the atomic concentration of the element M, and [Zn] means the atomic concentration of Zn.

A crystal of an In-M-Zn oxide is known to have a homologous structure and is represented by InMO₃(ZnO)ₘ (m is a natural number). Since In and M can be interchanged, the crystal can also be represented by In_{1+α}M_{1-α}O₃(ZnO)ₘ. This composition is represented by any of dashed lines denoted as [In]:[M]:[Zn]=1+α:1−α:1, [In]:[M]:[Zn]=1+α:1−α:2, [In]:[M]:[Zn]=1+α:1−α:3, [In]:[M]:[Zn]=1+α:1−α:4, and [In]:[M]:[Zn]=1+α:1−α:5 in FIG. 31.

It is known that thick lines on the dashed lines in FIG. 31 indicate compositions which allow a single-phase solid solution range when oxides (raw materials) are mixed and sintered at 1350° C., for example. Coordinates denoted by square symbols in FIG. 31 correspond to known compositions with which a spinel crystal structure is likely to be mixed.

For example, a compound represented by ZnM₂O₄, such as ZnGa₂O₄, is known as a compound having a spinel crystal structure. When the composition is in the neighborhood of ZnM₂O₄, that is, the composition is close to (In, Zn, M)=(0, 1, 2) as shown in FIG. 31, a spinel crystal structure is likely to be formed or mixed. Furthermore, it is particularly preferable that the CAAC-OS film have no spinel crystal structure.

In addition, to increase carrier mobility, the indium content is preferably increased. In an oxide semiconductor containing indium, the element M, and zinc, the s orbital of heavy metal mainly contributes to carrier transfer, and when the indium content in the oxide semiconductor is increased, overlaps of the s orbitals of In atoms are increased; therefore, an oxide having a high content of indium has higher mobility than an oxide having a low content of indium. Therefore, an oxide having a high content of indium is used as an oxide semiconductor film, so that carrier mobility can be increased.

The composition of the semiconductor 662 in FIGS. 1A to 1D is preferably in the neighborhood of the composition represented by the thick line in FIG. 31. When such a composition is employed, the channel formation region of the transistor can have a high proportion of CAAC. Furthermore, in the case where the indium content in the semiconductor 662 is increased, the on-state current of the transistors can be increased.

When the channel formation region of the transistor includes a CAAC-OS as described above, a transistor having high reliability and high on-state current can be provided. In addition, a transistor capable of operating at high frequency can be provided.

When a CAAC-OS is deposited by sputtering, because of heating of a substrate surface (the surface on which the CAAC-OS is deposited), space heating, or the like, the composition of the film is sometimes different from that of a target as a source or the like. For example, since zinc oxide sublimates more easily than indium oxide, gallium oxide, or the like, the source and the film are likely to have different compositions. Thus, a source is preferably selected taking into account the change in composition. Note that a difference between the compositions of the source and the film is also affected by pressure or gas used for the deposition as well as temperature.

In the case where the CAAC-OS is deposited by sputtering, a target including a polycrystalline structure is preferably used.

### <Structure Example 2 of Transistor>

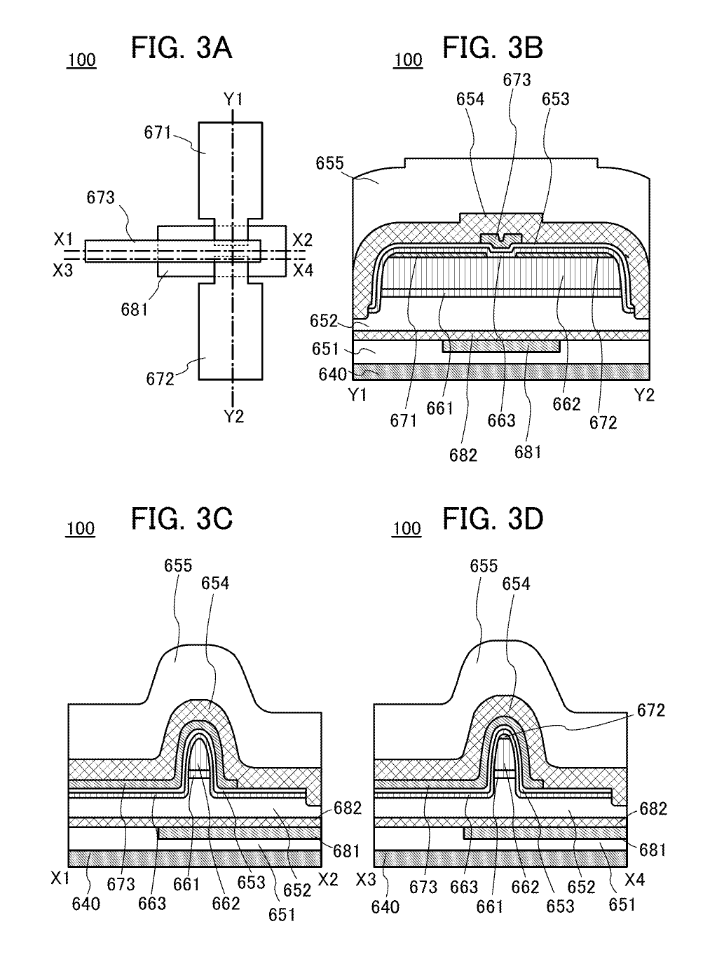

Although the example where one gate electrode is provided in the transistor is illustrated in FIGS. 1A to 1D, one embodiment of the present invention is not limited thereto. A plurality of gate electrodes may be provided in the transistor. FIGS. 3A to 3D illustrate an example where the transistor 100 in FIGS. 1A to 1D is provided with a conductive film 681 as a second gate electrode. FIG. 3A is a top view. FIG. 3B illustrates a cross section taken along dashed-dotted line Y1-Y2 in FIG. 3A. FIG. 3C illustrates a cross section taken along dashed-dotted line X1-X2 in FIG. 3A. FIG. 3D illustrates a cross section taken along dashed-dotted line X3-X4 in FIG. 3A. In FIGS. 3A to 3D, some components are scaled up or down or omitted for easy understanding.

FIGS. 3A to 3D differ from FIGS. 1A to 1D in that an insulating film 651, the conductive film 681, and an insulating film 682 are provided between the substrate 640 and the insulating film 652.

The insulating film 651 has a function of electrically isolating the substrate 640 and the conductive film 681 from each other. The insulating film 651 may be formed using an insulator containing one or more of aluminum oxide, aluminum nitride oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide. Alternatively, the insulating film 651 may be formed using an organic resin such as a polyimide resin, a polyamide resin, an acrylic resin, a siloxane resin, an epoxy resin, or a phenol resin. The insulating film 651 may be a stack of any of the above materials.

Any of the materials that can be used for the conductive film 673 can be used for the conductive film 681. The conductive film 681 functions as a second gate electrode. The conductive film 681 may be supplied with a constant potential, or a potential or a signal that is the same as that supplied to the conductive film 673.

The insulating film 682 has a function of preventing oxygen contained in the insulating film 652 from decreasing by bonding to metal contained in the conductive film 681. Any of the materials that can be used for the insulating film 654 can be used for the insulating film 682.

### <Structure Example 3 of Transistor>

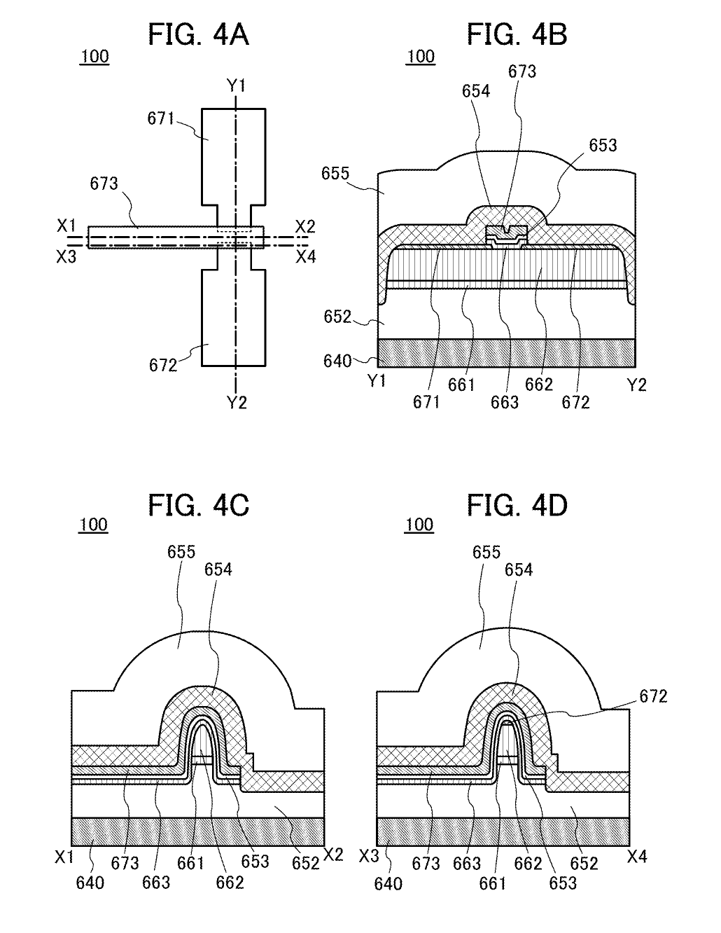

In the transistor 100 in FIGS. 1A to 1D, the semiconductor 663 and the insulating film 653 may be etched at the same time as the conductive film 673. FIGS. 4A to 4D illustrate an example. FIG. 4A is a top view. FIG. 4B illustrates a cross section taken along dashed-dotted line Y1-Y2 in FIG. 4A. FIG. 4C illustrates a cross section taken along dashed-dotted line X1-X2 in FIG. 4A. FIG. 4D illustrates a cross section taken along dashed-dotted line X3-X4 in FIG. 4A. In FIGS. 4A to 4D, some components are scaled up or down or omitted for easy understanding.

In FIGS. 4A to 4D, the semiconductor 663 and the insulating film 653 are provided only below the conductive film 673 and are removed in other regions.

### <Structure Example 4 of Transistor>

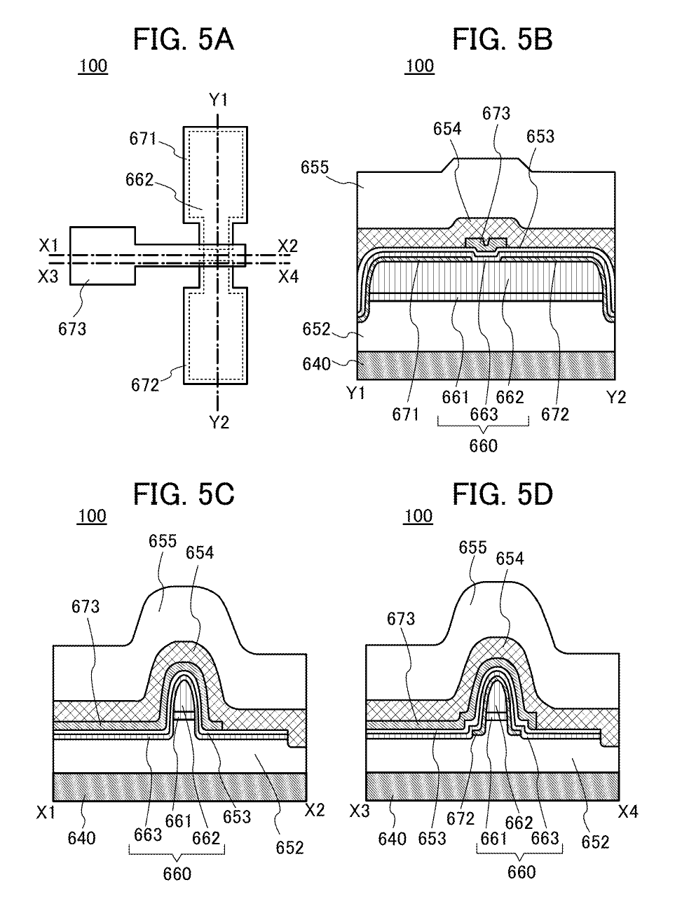

In the transistor 100 in FIGS. 1A to 1D, the conductive films 671 and 672 may be in contact with side surfaces of the semiconductors 661 and 662. FIGS. 5A to 5D illustrate an example. FIG. 5A is a top view. FIG. 5B illustrates a cross section taken along dashed-dotted line Y1-Y2 in FIG. 5A. FIG. 5C illustrates a cross section taken along dashed-dotted line X1-X2 in FIG. 5A. FIG. 5D illustrates a cross section taken along dashed-dotted line X3-X4 in FIG. 5A. In FIGS. 5A to 5D, some components are scaled up or down or omitted for easy understanding.

### <Structure Example 5 of Transistor>

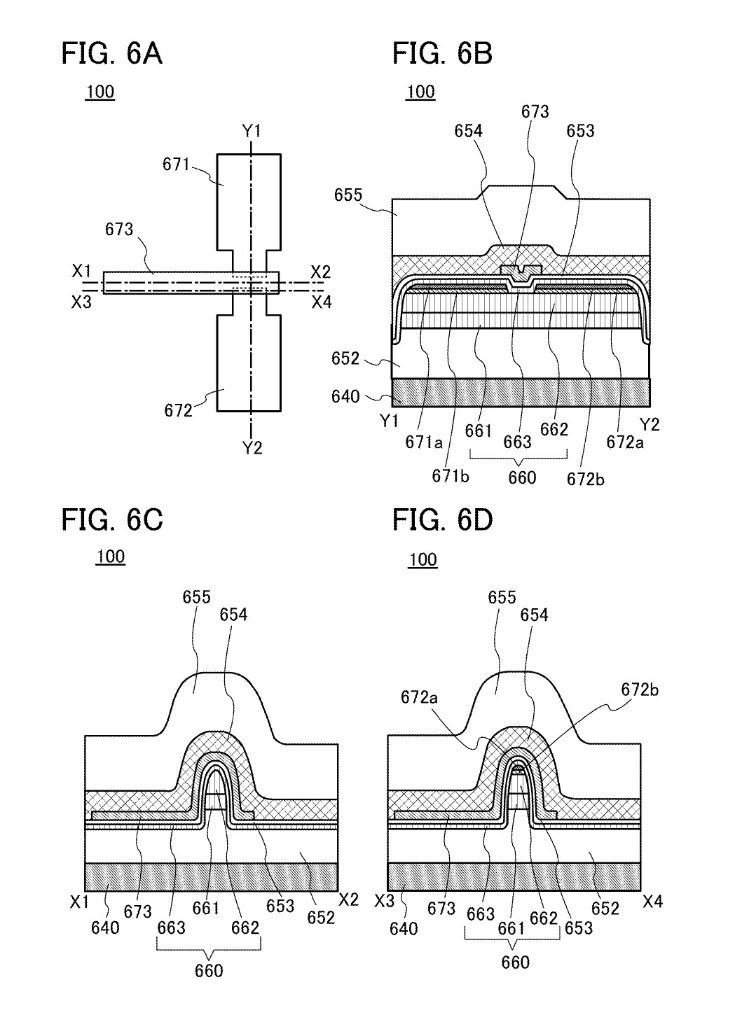

In the transistor 100 in FIGS. 1A to 1D, the conductive film 671 may have a layered structure of conductive films 671a and 671b. In addition, the conductive film 672 may have a layered structure of conductive films 672a and 672b. FIGS. 6A to 6D illustrate an example. FIG. 6A is a top view. FIG. 6B illustrates a cross section taken along dashed-dotted line Y1-Y2 in FIG. 6A. FIG. 6C illustrates a cross section taken along dashed-dotted line X1-X2 in FIG. 6A. FIG. 6D illustrates a cross section taken along dashed-dotted line X3-X4 in FIG. 6A. In FIGS. 6A to 6D, some components are scaled up or down or omitted for easy understanding.

The conductive films 671b and 672b may be formed using a transparent conductor, an oxide semiconductor, a nitride semiconductor, or an oxynitride semiconductor, for example. The conductive films 671b and 672b may be formed using, for example, a film containing indium, tin, and oxygen, a film containing indium and zinc, a film containing indium, tungsten, and zinc, a film containing tin and zinc, a film containing zinc and gallium, a film containing zinc and aluminum, a film containing zinc and fluorine, a film containing zinc and boron, a film containing tin and antimony, a film containing tin and fluorine, a film containing titanium and niobium, or the like. Alternatively, any of these layers may contain hydrogen, carbon, nitrogen, silicon, germanium, or argon.

The conductive films 671b and 672b may have a property of transmitting visible light. Alternatively, the conductive films 671b and 672b may have a property of not transmitting visible light, ultraviolet light, infrared light, or an X-ray by reflecting or absorbing it. In some cases, such a property can suppress a change in electrical characteristics of the transistor due to stray light.

The conductive films 671b and 672b may preferably be formed using a layer that does not form a Schottky barrier with the semiconductor 662 or the like. Accordingly, on-state characteristics of the transistor can be improved.

The conductive films 671a and 672a may have a single-layer structure or a layered structure of a conductor containing, for example, one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy film or a compound film may be used, for example, and a conductor containing aluminum, a conductor containing copper and titanium, a conductor containing copper and manganese, a conductor containing indium, tin, and oxygen, a conductor containing titanium and nitrogen, or the like may be used.

Note that the conductive films 671b and 672b preferably have higher resistance than the conductive films 671a and 672a according to circumstances. The conductive films 671b and 672b preferably have lower resistance than the channel of the transistor according to circumstances. For example, the conductive films 671b and 672b may have a resistivity of higher than or equal to 0.1 Ωcm and lower than or equal to 100 Ωcm, higher than or equal to 0.5 Ωcm and lower than or equal to 50 Ωcm, or higher than or equal to 1 Ωcm and lower than or equal to 10 Ωcm. The conductive films 671b and 672b having resistivity within the above range can reduce electric field concentration in a boundary portion between the channel and the drain. Therefore, a change in electrical characteristics of the transistor can be suppressed. In addition, punch-through current generated by an electric field from the drain can be reduced. Thus, a transistor with small channel length can have favorable saturation characteristics. Note that in a circuit configuration where the source and the drain do not interchange, only one of the conductive films 671b and 672b (e.g., the layer on the drain side) is preferably provided according to circumstances.

### <Structure Example 6 of Transistor>

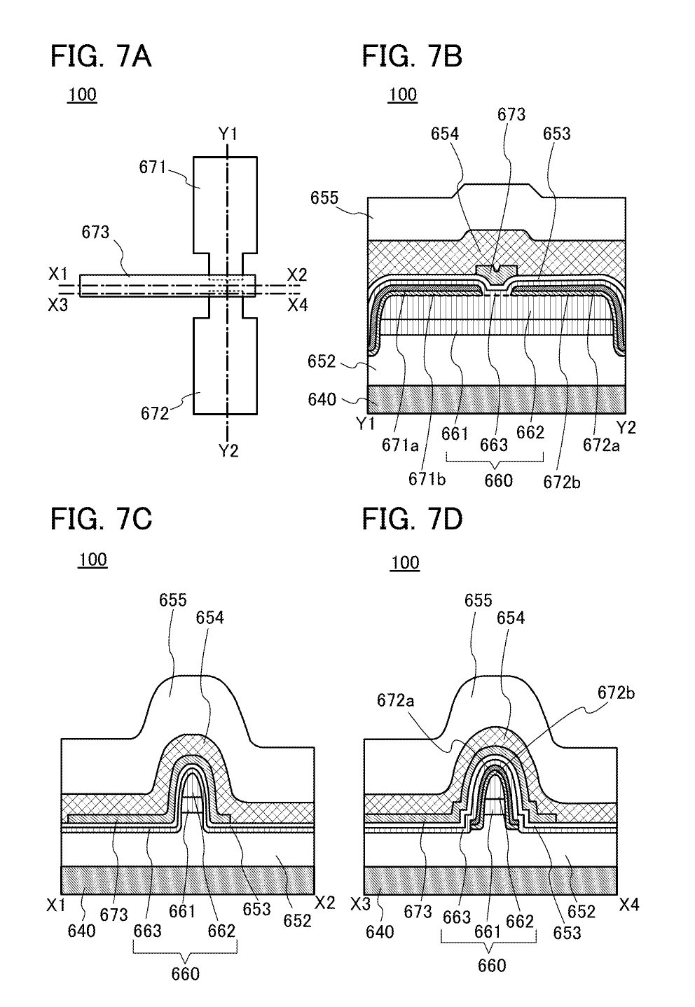

In the transistor in FIGS. 5A to 5D, the conductive film 671 may have a layered structure of the conductive films 671a and 671b. In addition, the conductive film 672 may have a layered structure of the conductive films 672a and 672b. FIGS. 7A to 7D illustrate an example. FIG. 7A is a top view. FIG. 7B illustrates a cross section taken along dashed-dotted line Y1-Y2 in FIG. 7A. FIG. 7C illustrates a cross section taken along dashed-dotted line X1-X2 in FIG. 7A. FIG. 7D illustrates a cross section taken along dashed-dotted line X3-X4 in FIG. 7A. In FIGS. 7A to 7D, some components are scaled up or down or omitted for easy understanding.

The description of FIGS. 6A to 6D may be referred to for the details of the conductive films 671a and 671b and the conductive films 672a and 672b in FIGS. 7A to 7D.

The structures, the methods, and the like described in this embodiment can be combined with any of the structures, the methods, and the like described in the other embodiments as appropriate.

### Embodiment 2

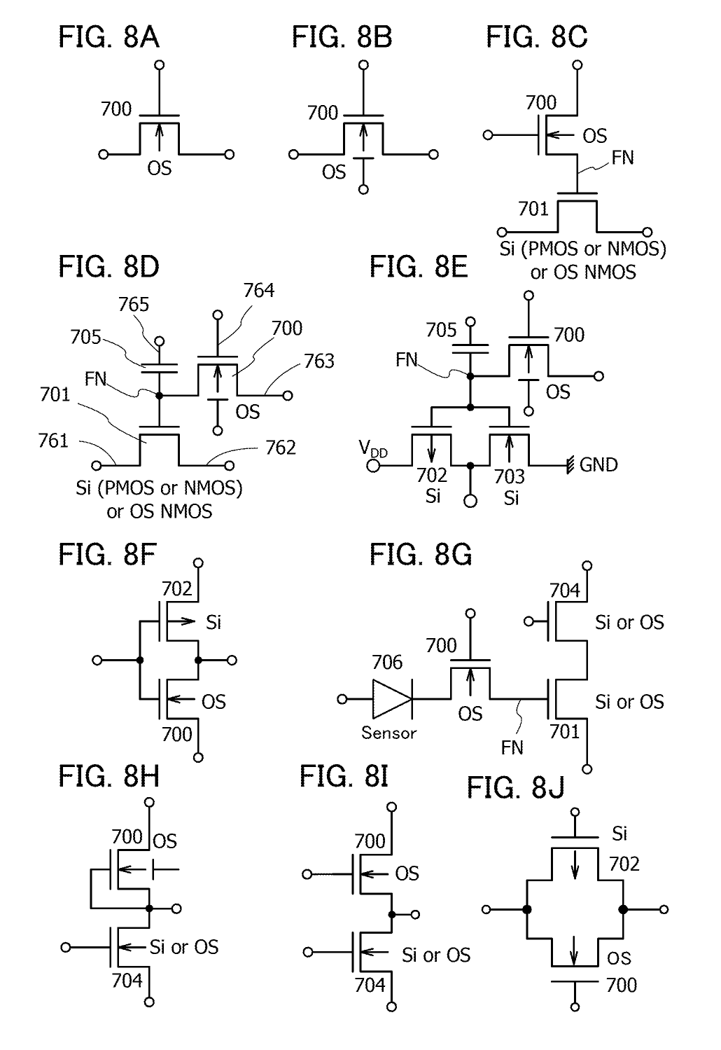

In this embodiment, examples of a circuit applicable to a semiconductor device in one embodiment of the present invention are described with reference to FIGS. 8A to 8J.

Examples of a circuit including a transistor with an active layer of an oxide semiconductor or a transistor with an active layer of silicon are illustrated in FIGS. 8A to 8J. Hereinafter, a transistor with an active layer of an oxide semiconductor is referred to as an OS transistor, and a transistor with an active layer of silicon is referred to as a Si transistor. In addition, a p-channel Si transistor is referred to as a p-Si transistor, and an n-channel Si transistor is referred to as an n-Si transistor. An OS transistor is an n-channel transistor unless otherwise specified. Furthermore, for convenience, in FIGS. 8A to 8J, a p-channel transistor and an n-channel transistor are described as PMOS and NMOS, respectively.

The channel length of an OS transistor is preferably greater than or equal to 1 nm and less than 100 nm, more preferably greater than or equal to 5 nm and less than or equal to 60 nm, for facilitating manufacturing, increasing integration degree, and utilizing advantages of the OS transistor with small short-channel effect. For formation of a Si transistor over the same substrate as the OS transistor, the channel length of the Si transistor is preferably greater than or equal to 1 nm and less than 100 nm, more preferably greater than or equal to 5 nm and less than or equal to 60 nm, or greater than or equal to 5 nm and less than or equal to 30 nm.

Circuits in FIGS. 8A and 8B each include a transistor 700, and function as a switching circuit, for example. The transistor 700 is an OS transistor. The transistor 700 in FIG. 8B is a dual-gate OS transistor including a first gate (top gate or front gate) and a second gate (back gate). The on-state characteristics and off-state characteristics can be improved by controlling the first gate and the second gate separately.

A circuit in FIG. 8C includes the transistor 700, a transistor 701, and a node FN, and can function as a storage circuit by holding a potential at the node FN. In FIG. 8C, the transistor 700 is an OS transistor. The transistor 701 may be a p-Si transistor, an n-Si transistor, or an OS transistor.

A circuit in FIG. 8D includes the transistors 700 and 701, a capacitor 705, and the node FN. The circuit in FIG. 8D can function as a storage circuit. Here, the transistor 700 is a dual-gate OS transistor. The transistor 701 may be a p-Si transistor, an n-Si transistor, or an OS transistor.

When the transistors 700 and 701 in the circuits in FIGS. 8C and 8D are OS transistors, it is not necessary to use a silicon substrate, and a light-transmitting substrate such as a glass substrate or a quartz substrate, a metal substrate, or the like, can be used.

In downsizing, an n-channel transistor needs complicated steps such as formation of an LDD or a distortion compared with a p-channel transistor. An OS transistor does not need complicated steps such as formation of an LDD or a distortion. Therefore, when the transistor 701 is a p-Si transistor and the transistor 700 is an OS transistor in the circuits in FIGS. 8C and 8D, manufacturing steps can be simplified.

Since an OS transistor does not need a high-temperature process at higher than or equal to 900° C., it is more suitable for integration than a Si transistor. In addition, the OS transistor and other semiconductor elements can be stacked, and a semiconductor device with high integration degree in which elements are three-dimensionally integrated can be provided with the use of the OS transistors in the circuit. That is, since the OS transistor can be formed by a lower-temperature process than the Si transistor, when the OS transistor is formed over the Si transistor, a semiconductor device with high reliability and high performance can be provided.

A circuit in FIG. 8E is a modification example of the circuit in FIG. 8D, and includes transistors 702 and 703 electrically connected to each other in series instead of the transistor 701. For example, a first terminal of the transistor 702 is electrically connected to a wiring or an electrode that is supplied with a high power supply potential (V_{DD}), and a second terminal of the transistor 703 is electrically connected to a wiring or an electrode that is supplied with a ground potential (GND). The transistor 700 is a dual-gate OS transistor, the transistor 702 is a p-Si transistor, and the transistor 703 is an n-Si transistor. The transistors 702 and 703 constitute a CMOS inverter circuit. The transistor 700 can be manufactured by a low temperature process, and is compatible with a general manufacturing process of a Si transistor; thus, it is easy to form the transistor 700 over the transistors 702 and 703.

FIG. 8F illustrates an example of a CMOS inverter circuit. The transistor 700 is an OS transistor, and the transistor 702 is a p-Si transistor. The transistor 700 can be manufactured by a low temperature process, and is compatible with a general manufacturing process of a Si transistor; thus, it is easy to form the transistor 700 over the transistor 702.

A circuit in FIG. 8G includes the transistors 700 and 701, a transistor 704, a diode 706, and the node FN. The transistors 701 and 704 are electrically connected to each other in series. A gate of the transistor 701 is electrically connected to an output terminal of the diode 706 through the transistor 700. An input terminal of the diode 706, a gate of the transistor 700, a first terminal of the transistor 701, and a second terminal of the transistor 704 are electrically connected to unillustrated wirings or electrodes that are different from each other. The circuit including the transistors 700, 701, and 704, the diode 706, and the node FN can function as a storage circuit as in the circuits in FIG. 8C and the like. Data based on a potential between the input terminal and the output terminal of the diode 706 can be held at the node FN. When a photodiode is used as the diode 706, the diode 706 can function as a sensor element. In that case, the circuit in FIG. 8G can function as an optical sensor circuit. A potential based on photo current flowing through the diode 706 can be held at the node FN.

A sensor element used in the circuit in FIG. 8G is not limited to an optical sensor element, and a variety of sensors can be used. An example of the sensor element is as follows: an element having a function of measuring or detecting force, displacement, position, speed, acceleration, angular velocity, rotational frequency, distance, light (e.g., visible light or infrared light), electromagnetism (e.g., brain waves), magnetism, temperature, chemical substance, sound, time, hardness, electric field, current, voltage, electric power, radiation, flow rate, humidity, gradient, oscillation, smell, or the like, and converting the result into a voltage signal or a current signal. For example, a temperature sensor circuit where two resistors with different temperature characteristics are connected to each other in series may be provided instead of the photodiode.

In the circuit in FIG. 8G, the transistor 700 is an OS transistor. Each of the transistors 701 and 704 may be a p-Si transistor, an n-Si transistor, or an OS transistor. The diode 706 may be a photodiode using silicon, for example. When the transistors 701 and 704 are Si transistors, it is easy to form the transistor 700 over the transistors 701 and 704 because the transistor 700 can be manufactured by a low temperature process, and is compatible with a general manufacturing process of a Si transistor.

In addition, in the circuit in FIG. 8G, when one of the transistors 701 and 704 is a Si transistor and the other of the transistors 701 and 704 is an OS transistor, a circuit in which high-speed operation characteristics of the Si transistor are combined with low-leakage current characteristics of the OS transistor can be formed.

Furthermore, in the circuit in FIG. 8G, the manufacturing steps can be more simplified when the transistors 701 and 704 are OS transistors. When the transistors are downsized, an OS transistor can obtain frequency characteristics equivalent to that of a Si transistor; thus, a circuit in which high-speed operation characteristics are combined with high-speed operation characteristics and low-leakage current characteristics can be formed even with the structure.

A circuit in FIG. 8H includes the transistors 700 and 704 electrically connected to each other in series. A first gate of the transistor 700 is electrically connected to a first terminal of the transistor 700, and a second terminal of the transistor 700 is electrically connected to an unillustrated wiring or electrode. The first gate may be electrically connected to the second terminal. A first terminal of the transistor 704 is electrically connected to an unillustrated wiring or electrode. The circuit in FIG. 8H can function as an enhancement/depletion type inverter circuit. The transistor 700 is a dual-gate OS transistor, and can control characteristics of the circuit (inverter circuit) in FIG. 8H when a second gate potential is variable. The transistor 704 can be an OS transistor or an n-Si transistor.

A circuit in FIG. 8I includes the transistors 700 and 704 electrically connected to each other in series, as in the circuit in FIG. 8H. The circuit in FIG. 8I differs from the circuit in FIG. 8H in that the gate of the transistor 700 is electrically connected to an unillustrated wiring or electrode. The circuit in FIG. 8I can function as an enhancement/enhancement type inverter circuit. The gate potential of the transistor 700 may be fixed or variable. The transistor 700 is an OS transistor. The transistor 704 may be an OS transistor or an n-Si transistor. The gate potential of the transistor 704 may be fixed or variable.

When each of the transistors 704 in FIGS. 8H and 8I is a Si transistor, the transistor 700 can be formed over the transistor 704, as in the circuit in FIG. 8C and the like.

A circuit diagram in FIG. 8J illustrates a configuration in which sources of the transistors 700 and 702 are connected to each other and drains of the transistors 700 and 702 are connected to each other. The transistor 700 is an OS transistor, and the transistor 702 is a p-Si transistor. With such a configuration, the transistors can function as what is called an analog switch. The transistor 700 can be manufactured by a low temperature process, and is compatible with a general manufacturing process of a Si transistor; thus, it is easy to form the transistor 700 over the transistor 702.

For an OS transistor used for the circuits in FIGS. 8A to 8J, a second gate electrode may be provided or no second gate electrode may be provided as necessary.

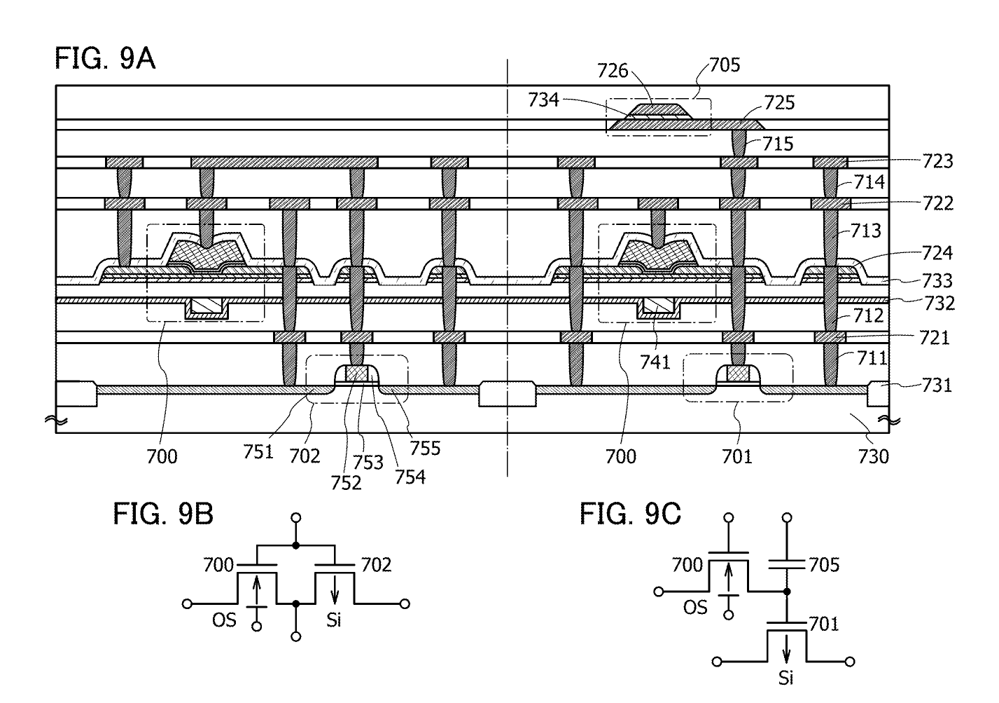

The circuits (semiconductor devices) in FIGS. 8A to 8J can be formed over one substrate. Therefore, a plurality of circuits with different functions or performance can be formed over one substrate. For example, FIG. 9A illustrates a semiconductor device when the circuits in FIGS. 8D and 8F are formed over one substrate.

FIG. 9A is a cross-sectional view illustrating a structure example of the semiconductor device. The left portion corresponds to a circuit in FIG. 9B, and the right portion corresponds to a circuit in FIG. 9C. The circuit diagram in FIG. 9B corresponds to the circuit diagram in FIG. 8F, and the circuit diagram in FIG. 9C corresponds to the circuit diagram in FIG. 8D. In the semiconductor device in FIG. 9A, the transistors 700 are OS transistors, and the transistors 701 and 702 are p-Si transistors. FIG. 9A illustrates the cross-sectional structure of each transistor in a channel length direction.

The semiconductor device in FIG. 9A includes the transistors 700 to 702, the capacitor 705, a substrate 730, an element isolation layer 731, insulating films 732 and 733, plugs 711 to 715, and wirings 721, 722, 723, 724, and 741. Note that in FIG. 9A, reference numerals are given to one of the plugs and one of the wirings formed in the same hierarchy to avoid complexity.

As the transistor 700, the transistor described in Embodiment 1 can be used.

The transistors 701 and 702 each include impurity regions 751 and 755 functioning as a source region and a drain region, a gate electrode 752, a gate insulating film 753, and a sidewall insulating layer 754.

The transistors 701 and 702 each include a first semiconductor material, and the transistor 700 includes a second semiconductor material. The first semiconductor material and the second semiconductor material preferably have different band gaps. For example, the first semiconductor material can be a semiconductor material other than an oxide semiconductor (such as silicon (including strained silicon), germanium, silicon germanium, silicon carbide, gallium arsenide, aluminum gallium arsenide, indium phosphide, gallium nitride, or an organic semiconductor), and the second semiconductor material can be an oxide semiconductor. A transistor including a material other than an oxide semiconductor, such as single crystal silicon, can operate at high speed easily. In contrast, a transistor including an oxide semiconductor and described in Embodiment 1 as an example can have excellent subthreshold characteristics and a minute structure. Furthermore, the transistor can operate at high speed because of its high switching speed and has low leakage current because of its low off-state current.

Each of the transistors 701 and 702 may be either an n-channel transistor or a p-channel transistor, and an appropriate transistor may be used depending on a circuit. In FIG. 9A, each of the transistors 701 and 702 is a p-channel transistor.

Moreover, each of the transistors 701 and 702 may include an impurity region functioning as a lightly doped drain (LDD) region or an extension region below the sidewall insulating layer 754. In particular, when each of the transistors 701 and 702 is an n-channel transistor, the LDD region or the extension region is preferably provided to suppress deterioration due to hot carriers.

As each of the transistors 701 and 702, a transistor containing silicide (salicide) or a transistor that does not include the sidewall insulating layer 754 may be used. When a structure that contains silicide (salicide) is used, the resistance of the source region and the drain region can be further lowered and the speed of the semiconductor device can be increased. Furthermore, the semiconductor device can be operated at low voltage; thus, power consumption of the semiconductor device can be reduced.

The wiring 741 functions as the back gate of the transistor 700; however, the wiring 741 may be omitted according to circumstances.

The capacitor 705 includes a first electrode 725, a second electrode 726, and an insulating film 734.

A single crystal semiconductor substrate or a polycrystalline semiconductor substrate of silicon or silicon carbide, a compound semiconductor substrate of silicon germanium, a silicon-on-insulator (SOI) substrate, or the like can be used as the substrate 730. A transistor formed using a semiconductor substrate can operate at high speed easily. Note that in the case where a p-type single crystal silicon substrate is used as the substrate 730, an impurity element imparting n-type conductivity may be added to part of the substrate 730 to form an n-well, and a p-type transistor can be formed in a region where the n-well is formed. As the impurity element imparting n-type conductivity, phosphorus (P), arsenic (As), or the like can be used. As the impurity element imparting p-type conductivity, boron (B) or the like may be used.

For example, a glass substrate, a quartz substrate, a plastic substrate, a metal substrate, a flexible substrate, an attachment film, paper including a fibrous material, a base film, or the like may be used as the substrate 730. Examples of a glass substrate include a barium borosilicate glass substrate, an aluminoborosilicate glass substrate, and a soda lime glass substrate. Examples of a metal substrate include a stainless steel substrate, a substrate including stainless steel foil, a tungsten substrate, and a substrate including tungsten foil. Examples of a flexible substrate include a flexible synthetic resin such as plastics typified by polyethylene terephthalate (PET), polyethylene naphthalate (PEN), and polyethersulfone (PES), and acrylic. Examples of an attachment film include attachment films formed using polypropylene, polyester, polyvinyl fluoride, and polyvinyl chloride. Examples of a base material film include films formed using polyester, polyamide, polyimide, aramid, epoxy, an inorganic vapor deposition film, and paper.

Note that a semiconductor element may be formed using one substrate and then transferred to another substrate. Examples of a substrate to which a semiconductor element is transferred include, in addition to the above-described substrates, a paper substrate, a cellophane substrate, an aramid film substrate, a polyimide film substrate, a stone substrate, a wood substrate, a cloth substrate (including a natural fiber (e.g., silk, cotton, and hemp), a synthetic fiber (e.g., nylon, polyurethane, and polyester), a regenerated fiber (e.g., acetate, cupra, rayon, and regenerated polyester), and the like), a leather substrate, and a rubber substrate. When such a substrate is used, a transistor with excellent properties or a transistor with low power consumption can be formed, a device with high durability or high heat resistance can be provided, or reduction in weight or thickness can be achieved.

The transistors 701 and 702 are isolated from other transistors formed on the substrate 730 by the element isolation layer 731. The element isolation layer 731 can be formed using an insulator containing one or more materials selected from aluminum oxide, aluminum oxynitride, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, tantalum oxide, and the like.

The wiring 741 functions as a second gate electrode of the transistor 700. The wiring 741 may be formed using a material that can be used for the wirings 721 to 723. Note that the wiring 741 may be omitted according to circumstances.

Here, in the case where a silicon-based semiconductor material is used for the transistors 701 and 702 provided in a lower portion, hydrogen in an insulating film provided in the vicinity of the semiconductor films of the transistors 701 and 702 terminates dangling bonds of silicon; accordingly, the reliability of the transistors 701 and 702 can be improved. Meanwhile, in the case where an oxide semiconductor is used for the transistor 700 provided in an upper portion, hydrogen in an insulating film provided in the vicinity of the semiconductor film of the transistor 700 becomes a factor of generating carriers in the oxide semiconductor; thus, the reliability of the transistor 700 might be decreased. Therefore, in the case where the transistor 700 using an oxide semiconductor is stacked over the transistors 701 and 702 using a silicon-based semiconductor material, it is particularly effective that the insulating film 732 having a function of preventing diffusion of hydrogen is provided between the transistor 700 and the transistors 701 and 702. The insulating film 732 makes hydrogen remain in the lower portion, so that the reliability of the transistors 701 and 702 can be increased. In addition, since the insulating film 732 inhibits diffusion of hydrogen from the lower portion to the upper portion, the reliability of the transistor 700 can also be increased.

The insulating film 723 can be formed using aluminum oxide, aluminum oxynitride, gallium oxide, gallium oxynitride, yttrium oxide, yttrium oxynitride, hafnium oxide, hafnium oxynitride, or yttria-stabilized zirconia (YSZ), for example.

Furthermore, the insulating film 733 having a function of preventing diffusion of hydrogen is preferably formed over the transistor 700 to cover the transistor 700 including an oxide semiconductor film. For the insulating film 733, a material that is similar to that of the insulating film 732 can be used, and in particular, an aluminum oxide film is preferably used. The aluminum oxide film has a high shielding (blocking) effect of preventing penetration of both oxygen and impurities such as hydrogen and moisture. Thus, by using the aluminum oxide film as the insulating film 733 covering the transistor 700, release of oxygen from the oxide semiconductor film included in the transistor 700 can be prevented and entry of water and hydrogen into the oxide semiconductor film can be prevented.

The plugs 711 to 715 preferably have a single-layer structure or a layered structure of a conductive film containing a low-resistance material selected from copper (Cu), tungsten (W), molybdenum (Mo), gold (Au), aluminum (Al), manganese (Mn), titanium (Ti), tantalum (Ta), nickel (Ni), chromium (Cr), lead (Pb), tin (Sn), iron (Fe), and cobalt (Co); an alloy of such a low-resistance material; or a compound containing such a material as its main component. It is particularly preferable to use a high-melting-point material that has heat resistance and conductivity, such as tungsten or molybdenum. The plugs 711 to 715 are preferably formed using a low-resistance conductive material such as aluminum or copper. The plugs 711 to 715 are particularly preferably formed using a Cu—Mn alloy because manganese oxide formed at the interface with an insulator containing oxygen has a function of preventing Cu diffusion.

The wirings 721, 722, 723, and 741 and the electrodes 725 and 726 preferably have a single-layer structure or a layered structure of a conductive film containing a low-resistance material selected from copper (Cu), tungsten (W), molybdenum (Mo), gold (Au), aluminum (Al), manganese (Mn), titanium (Ti), tantalum (Ta), nickel (Ni), chromium (Cr), lead (Pb), tin (Sn), iron (Fe), and cobalt (Co); an alloy of such a low-resistance material; or a compound containing such a material as its main component. It is particularly preferable to use a high-melting-point material that has heat resistance and conductivity, such as tungsten or molybdenum. The wirings 721, 722, 723, and 741 and the electrodes 725 and 726 are preferably formed using a low-resistance conductive material such as aluminum or copper. The wirings 721, 722, 723, and 741 and the electrodes 725 and 726 are particularly preferably formed using a Cu—Mn alloy because manganese oxide formed at the interface with an insulator containing oxygen has a function of preventing Cu diffusion.

The wiring 724 can be formed in the same manufacturing steps as the source and the drain of the transistor 700.

Although the capacitor 705 is formed over the transistors 700 to 702 in FIG. 9A, the capacitor 705 may be formed over the transistors 701 and 702 and below the transistor 700.

The transistor described in Embodiment 1 may also be formed over the transistor 700 as necessary.

In FIG. 9A, regions where reference numerals and hatching patterns are not given show regions formed using an insulator. These regions can be formed using an insulator containing one or more materials selected from aluminum oxide, aluminum nitride oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, tantalum oxide, and the like. Alternatively, these regions can be formed using an organic resin such as a polyimide resin, a polyamide resin, an acrylic resin, a siloxane resin, an epoxy resin, or a phenol resin.

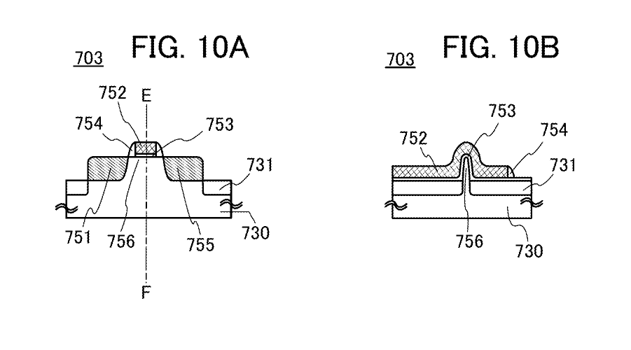

Here, the transistor 703 in FIGS. 10A and 10B may be used instead of the transistors 701 and 702. FIG. 10B illustrates a cross section taken along dashed dotted line E-F in FIG. 10A, which is perpendicular to a cross section in FIG. 10A. In the transistor 703, a semiconductor layer 756 (part of the semiconductor substrate) in which a channel is formed has a protruding portion, and the gate insulating film 753 and the gate electrode 752 are provided along top and side surfaces of the protruding portion. Furthermore, the element isolation layer 731 is provided between the transistors. The transistor 703 is also referred to as a FIN transistor because it utilizes a protruding portion of the semiconductor substrate. Note that an insulating film functioning as a mask for forming the protruding portion may be provided in contact with the top of the protruding portion. Although the protruding portion is formed by processing part of the semiconductor substrate here, a semiconductor layer having a protruding shape may be formed by processing an SOI substrate.

In the semiconductor device with the structure in FIG. 9A, a storage circuit (including a transistor and a floating node) and a peripheral circuit can be formed over one substrate. Since an OS transistor does not need heat treatment at higher than or equal to 900° C., the circuit can be formed by a lower-temperature process. In addition, the OS transistor has frequency characteristics equivalent to that of an n-channel transistor with an active layer of silicon. A CMOS circuit in which an OS transistor and a p-Si transistor is combined can operate at high speed.

In addition, our study shows that the dependence of field-effect mobility of an OS transistor on channel length is not as large as the dependence of field-effect mobility of a Si transistor on channel length. Moreover, there is no clear reduction in field-effect mobility of an OS transistor even when channel length is shortened from 10 μm to 100 nm.

Therefore, when an OS transistor with a channel length of less than or equal to 10 μm is used, a difference in field-effect mobility between the OS transistor and a Si transistor becomes smaller than a difference when the channel length of the OS transistor is greater than or equal to 10 μm. When an OS transistor with a channel length of less than or equal to 100 nm is used, a difference in field-effect mobility can be reduced; specifically, the field-effect mobility of the OS transistor can be approximately 1/30, preferably 1/10, more preferably ⅓ of a Si transistor.

When an OS transistor is used for a 100-nm-node transistor, it is possible to achieve field-effect mobility equivalent to that of a Si transistor. Thus, a miniaturized OS transistor can achieve switching speed and frequency characteristics that are equivalent to those of the Si transistor.

In addition, an OS transistor has low off-state current. In a circuit using an OS transistor, capacitance for holding charge can be low because of the low off-state current. Thus, a miniaturized OS transistor can achieve switching speed and frequency characteristics that are equivalent to those of the Si transistor.

The structure of this embodiment can be combined with any of the structures described in the other embodiments or examples as appropriate.

### Embodiment 3

In this embodiment, an example of a storage device including a transistor in one embodiment of the present invention is described with reference to drawings. The storage device can retain stored data even when power is not supplied and has an unlimited number of write cycles.

The circuit in FIG. 8D can function as a memory cell. The memory cell in FIG. 8D includes the transistor 701 formed using a first semiconductor material, the transistor 700 formed using a second semiconductor material, and the capacitor 705. As the transistor 700, the transistor described in Embodiment 1 can be used.

The transistor 700 is a transistor in which a channel is formed in a semiconductor layer including an oxide semiconductor. Since the off-state current of the transistor 700 is low, stored data can be retained for a long time owing to such a transistor. In other words, a storage device in which refresh operation is not needed or the frequency of refresh operation is extremely low can be provided, which results in a sufficient reduction in power consumption.

In FIG. 8D, a wiring 761 is electrically connected to a source of the transistor 701. A wiring 762 is electrically connected to a drain of the transistor 701. A wiring 763 is electrically connected to one of the source and the drain of the transistor 700. A wiring 764 is electrically connected to the gate of the transistor 700. A gate of the transistor 701 and the other of the source and the drain of the transistor 700 are electrically connected to a first terminal of the capacitor 705. A wiring 765 is electrically connected to a second terminal of the capacitor 705.

The memory cell in FIG. 8D utilizes a characteristic in which the potential of the gate of the transistor 701 can be retained, so that data can be written, retained, and read as follows.

Data writing and data retention are described. First, the potential of the wiring 764 is set to a potential at which the transistor 700 is turned on, so that the transistor 700 is turned on. Accordingly, the potential of the wiring 763 is supplied to the gate of the transistor 701 and the capacitor 705. That is, predetermined charge is supplied to the gate of the transistor 701 (writing). Here, charge for supplying either of two different potential levels (hereinafter referred to as low-level charge and high-level charge) is given. After that, the potential of the wiring 764 is set to a potential at which the transistor 700 is turned off, so that the transistor 700 is turned off. Thus, the charge given to the gate of the transistor 701 is held (storing).

Since the off-state current of the transistor 700 is extremely low, the charge of the gate of the transistor 701 is held for a long time.

Next, data reading is described. An appropriate potential (reading potential) is supplied to the wiring 765 while a predetermined potential (constant potential) is supplied to the wiring 761, so that the potential of the wiring 762 varies depending on the amount of charge held in the gate of the transistor 701. This is because in the case where the transistor 701 is an n-channel transistor, apparent threshold voltage Vₜₕ_{_{—}}_{H} when high-level charge is supplied to the gate of the transistor 701 is usually lower than apparent threshold voltage Vₜₕ_{_{—}}_{L} when low-level charge is supplied to the gate of the transistor 701. Here, apparent threshold voltage refers to the potential of the wiring 765 that is needed to turn on the transistor 701. Thus, when the potential of the wiring 765 is set to a potential V₀ that is between Vₜₕ_{_{—}}_{H} and Vₜₕ_{_{—}}_{L}, charge given to the gate of the transistor 701 can be determined. For example, in the case where the high-level charge is given in data writing, the transistor 701 is turned on when the potential of the wiring 765 is V₀ (>Vₜₕ_{_{—}}_{H}). In the case where the low-level charge is given in data writing, the transistor 701 remains in an off state even when the potential of the wiring 765 is set to V₀ (>Vₜₕ_{_{—}}_{L}). Therefore, the retained data can be read by determining the potential of the wiring 762.

Note that in the case where memory cells are arrayed, only data of a desired memory cell needs to be read. In the case where such data reading is not performed, the wiring 765 may be supplied with a potential at which the transistor 701 is turned off regardless of the state of the gate, that is, a potential lower than Vₜₕ_{_{—}}_{H}. Alternatively, the wiring 765 may be supplied with a potential at which the transistor 701 is turned on regardless of the state of the gate, that is, a potential higher than Vₜₕ_{_{—}}_{L}.

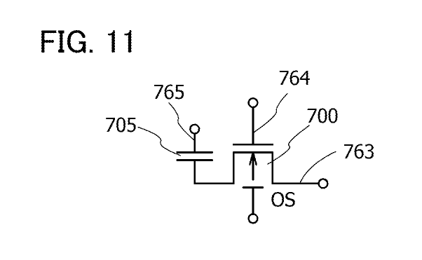

The memory cell in FIG. 11 differs from the memory cell in FIG. 8D in that the transistor 701 is not provided. Also in this case, data can be written and retained in a manner similar to the above.

Next, data reading is described. When the transistor 700 is turned on, the wiring 763 that is in a floating state and the capacitor 705 are electrically connected to each other, and the charge is redistributed between the wiring 763 and the capacitor 705. As a result, the potential of the wiring 763 is changed. The amount of change in the potential of the wiring 763 varies depending on the potential of the first terminal of the capacitor 705 (or the charge accumulated in the capacitor 705).

For example, the potential of the wiring 763 after the charge redistribution is (C_{B}×V_{B0}+C×V)/(C_{B}+C), where V is the potential of the first terminal of the capacitor 705, C is the capacitance of the capacitor 705, GB is the capacitance component of the wiring 763, and V_{B0} is the potential of the wiring 763 before the charge redistribution. Thus, it can be found that, assuming that the memory cell is in either of two states in which the potential of the first terminal of the capacitor 705 is V₁ and V₀ (V₁>V₀), the potential of the wiring 763 when the potential V₁ is held (=(C_{B}×V_{B0}+C×V₁)/(C_{B}+C)) is higher than the potential of the wiring 763 when the potential V₀ is held (=(C_{B}×V_{B0}+C×V₀)/(C_{B}+C)).

Then, by comparing the potential of the wiring 763 with a predetermined potential, data can be read.

In this case, a transistor including the first semiconductor material may be used in a driver circuit for driving a memory cell, and a transistor including the second semiconductor material may be stacked over the driver circuit as the transistor 700.

In this embodiment, when a transistor having a channel formation region formed using an oxide semiconductor and having extremely low off-state current is employed in the memory cell, stored data can be retained for an extremely long period. In other words, power consumption can be sufficiently reduced because refresh operation becomes unnecessary or the frequency of refresh operation can be extremely low. Moreover, stored data can be held for a long period even when power is not supplied (note that a potential is preferably fixed).

In addition, the memory cell in this embodiment does not require high voltage for writing data and does not have the problem of deterioration of elements. For example, unlike a conventional nonvolatile memory, it is not necessary to inject and extract electrons into and from a floating gate; thus, a problem such as deterioration of a gate insulating film does not arise at all. In other words, the semiconductor device in the disclosed invention does not have a limit on the number of write cycles that is a problem in a conventional nonvolatile memory, and reliability thereof is drastically improved. Furthermore, data is written depending on the on state and the off state of the transistor, so that high-speed operation can be easily achieved.

The structures, the methods, and the like described in this embodiment can be combined with any of the structures, the methods, and the like described in the other embodiments as appropriate.

### Embodiment 4

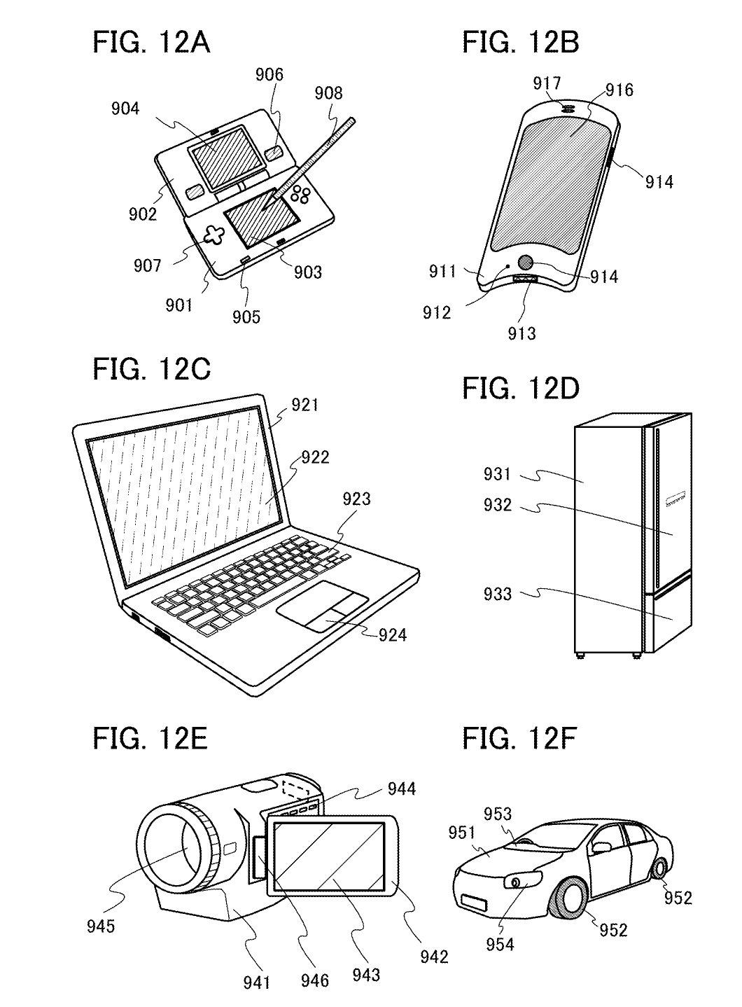

A semiconductor device in one embodiment of the present invention can be used for display devices, personal computers, or image reproducing devices provided with recording media (typically, devices that reproduce the content of recording media such as digital versatile discs (DVDs) and have displays for displaying the reproduced images). Furthermore, as electronic devices that can include the semiconductor device in one embodiment of the present invention, cellular phones, game machines (including portable game machines), portable information terminals, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATMs), vending machines, and the like can be given. FIGS. 12A to 12F illustrate specific examples of these electronic devices.

FIG. 12A illustrates a portable game machine, which includes housings 901 and 902, display portions 903 and 904, a microphone 905, speakers 906, an operation key 907, a stylus 908, and the like. Although the portable game machine in FIG. 12A has the two display portions 903 and 904, the number of display portions included in the portable game machine is not limited to this.

FIG. 12B illustrates a cellular phone, which includes a housing 911, a display portion 916, operation buttons 914, an external connection port 913, a speaker 917, a microphone 912, and the like. When the display portion 916 is touched with a finger or the like, data can be input into the cellular phone in FIG. 12B. Furthermore, operations such as making a call and inputting a letter can be performed by touch on the display portion 916 with a finger or the like. With the operation buttons 914, power ON/OFF can be switched. In addition, types of images displayed on the display portion 916 can be switched; for example, switching images from a mail creation screen to a main menu screen.

FIG. 12C illustrates a laptop, which includes a housing 921, a display portion 922, a keyboard 923, a pointing device 924, and the like.

FIG. 12D illustrates an electric refrigerator-freezer, which includes a housing 931, a refrigerator door 932, a freezer door 933, and the like.

FIG. 12E illustrates a video camera, which includes a first housing 941, a second housing 942, a display portion 943, operation keys 944, a lens 945, a joint 946, and the like. The operation keys 944 and the lens 945 are provided in the first housing 941, and the display portion 943 is provided in the second housing 942. The first housing 941 and the second housing 942 are connected to each other with the joint 946, and an angle between the first housing 941 and the second housing 942 can be changed with the joint 946. An image displayed on the display portion 943 may be switched in accordance with the angle between the first housing 941 and the second housing 942 at the joint 946.

FIG. 12F illustrates an ordinary vehicle, which includes a car body 951, wheels 952, a dashboard 953, lights 954, and the like.

Note that this embodiment can be combined with any of the other embodiments and examples in this specification as appropriate.

### Embodiment 5

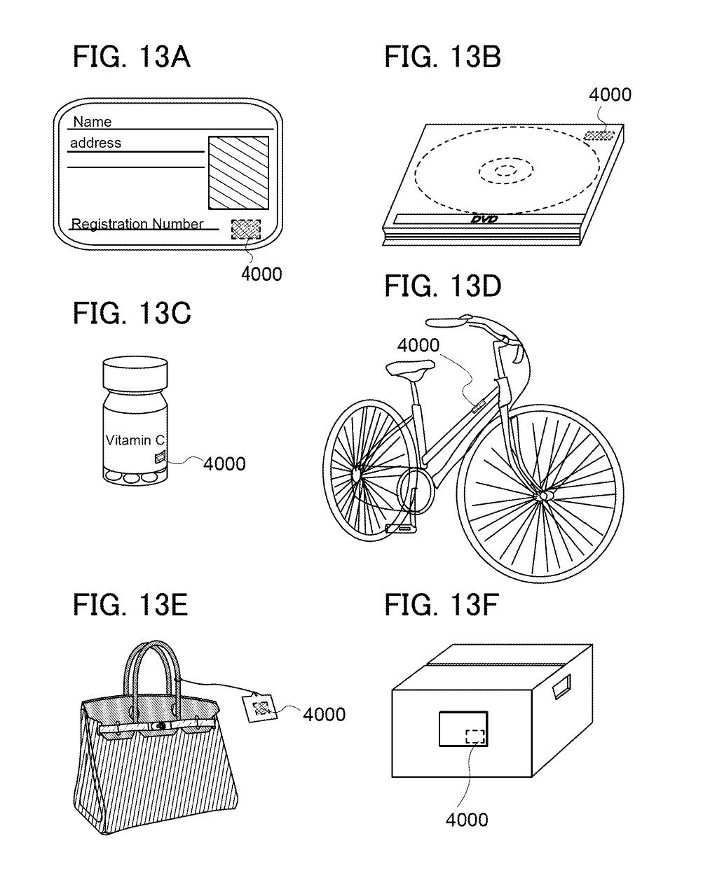

In this embodiment, application examples of an RF tag in one embodiment of the present invention are described with reference to FIGS. 13A to 13F. The RF tag is widely used and can be provided for, for example, products such as bills, coins, securities, bearer bonds, documents (e.g., driver's licenses or resident's cards, see FIG. 13A), recording media (e.g., DVDs or video tapes, see FIG. 13B), packaging containers (e.g., wrapping paper or bottles, see FIG. 13C), vehicles (e.g., bicycles, see FIG. 13D), personal belongings (e.g., bags or glasses), foods, plants, animals, human bodies, clothing, household goods, medical supplies such as medicine and chemicals, and electronic devices (e.g., liquid crystal display devices, EL display devices, television sets, or cellular phones), or tags on products (see FIGS. 13E and 13F).

An RF tag 4000 in one embodiment of the present invention is fixed to products by being attached to a surface thereof or embedded therein. For example, the RF tag 4000 is fixed to each product by being embedded in paper of a book, or embedded in an organic resin of a package. Since the RF tag 4000 in one embodiment of the present invention can be reduced in size, thickness, and weight, the RF tag 4000 can be fixed to a product without spoiling the design of the product. Furthermore, bills, coins, securities, bearer bonds, documents, or the like can have an identification function by being provided with the RF tag 4000 in one embodiment of the present invention, and the identification function can be utilized to prevent counterfeiting. Moreover, the efficiency of a system such as an inspection system can be improved by providing the RF tag in one embodiment of the present invention for packaging containers, recording media, personal belongings, foods, clothing, household goods, electronic devices, or the like. Vehicles can also have higher security against theft or the like by being provided with the RF tag in one embodiment of the present invention.

As described above, by using the RF tag in one embodiment of the present invention for each application described in this embodiment, power for operation such as data writing or data reading can be reduced, which results in an increase in the maximum communication distance. Moreover, data can be retained for an extremely long period even in a state where power is not supplied; thus, the RF tag in one embodiment of the present invention can be favorably used for application in which data is not frequently written or read.

Note that this embodiment can be combined with any of the other embodiments and examples in this specification as appropriate.

### Example 1

In this example, evaluation results of oxide semiconductor films that can be used for the transistors described in Embodiment 1 are described.

First, samples for evaluation were formed. Oxide semiconductor films were deposited over silicon wafers by DC sputtering.

In this example, two kinds of samples (Sample A and Sample B) were fabricated and evaluated. Sample A and Sample B have different oxide semiconductor films. Sample A was deposited using a polycrystalline target of an In—Ga—Zn oxide with an atomic ratio of In:Ga:Zn=1:1:1. Sample B was deposited using a polycrystalline target of an In—Ga—Zn oxide with an atomic ratio of In:Ga:Zn=4:2:4.1. Table 1 shows the deposition conditions of the oxide semiconductor films.

TABLE 1

| | | Gas flow rate | | Substrate | Pres- | |
|---|---|---|---|---|---|---|
| | Power | [sccm] | | temperature | sure | |
| | [kW] | Ar | O₂ | [° C.] | [Pa] | Target |
| Sample A | 0.5 | 30 | 15 | 300 | 0.7 | In:Ga:Zn = |
| | | | | | | 1:1:1 |
| Sample B | 0.2 | 20 | 10 | 200 | 0.4 | In:Ga:Zn = |
| | | | | | | 4:2:4.1 |

After deposition, each sample was subjected to heat treatment. The heat treatment was performed at 450° C. for 1 hour in a nitrogen atmosphere, and heat treatment was subsequently performed at 450° C. for 1 hour in an oxygen atmosphere in the same treatment chamber.

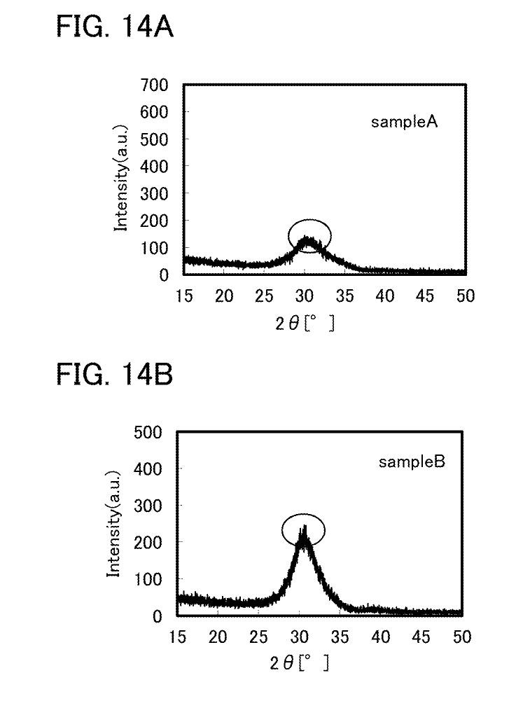

Evaluation results obtained with an XRD apparatus are shown in FIGS. 14A and 14B. FIGS. 14A and 14B show results of analysis by an out-of-plane method. The result of analysis of Sample A is shown in FIG. 14A, and the result of analysis of Sample B is shown in FIG. 14B.

A peak was observed at around 2θ=31° in each of Sample A and Sample B. This peak is derived from the (009) plane of an InGaZnO₄ crystal, which indicates that crystals in the oxide semiconductor film in each sample have c-axis alignment, and that the c-axes are aligned in a direction substantially perpendicular to a formation surface or the top surface of the oxide semiconductor film. When the half-width of the peak at around 2θ=31° in each sample was calculated, the half-width of Sample A was 4.68° and the half-width of Sample B was 3.47°. The half-width of Sample B was smaller than the half-width of Sample A. This indicates that Sample B has a higher proportion of CAAC than Sample A.

The half-width was obtained in such a manner that a background was subtracted and then the peak was fitted to the Lorentz function.

The concentration of each metal element in Sample A and Sample B was evaluated by inductively coupled plasma mass spectrometry (ICP-MS). Table 2 shows results.

TABLE 2

| | Atomic ratio | | |
|---|---|---|---|
| | In | Ga | Zn |
| Sample A | 1.00 | 0.99 | 0.66 |
| Sample B | 4.00 | 1.93 | 2.74 |

According to Table 2, as compared to the proportion of zinc atoms in the target, the proportion of zinc atoms in Sample A and Sample B was reduced by approximately 44%. In contrast, the difference in the proportions of indium atoms and gallium atoms between the target and each sample was only approximately 1 to 2%, and the proportions of indium atoms and gallium atoms were hardly reduced.

### Example 2

When the transistor described in Embodiment 1 has a channel formation region formed using a CAAC-OS and an s-channel structure, the transistor has excellent transistor characteristics even when channel length is decreased to less than or equal to 100 nm. In this example, the transistor 100 in FIGS. 1A to 1D was fabricated, and V_{G}-I_{D} characteristics of the transistor 100 were measured.

Two different kinds of transistors (hereinafter referred to as Transistor A and Transistor B) were fabricated and evaluated. As in FIGS. 1A to 1D, Transistors A and B each include three semiconductors (the semiconductors 661 to 663).

Transistors A and B each include a 20-nm-thick In—Ga—Zn oxide as the semiconductor 661, a 15-nm-thick In—Ga—Zn oxide as the semiconductor 662, and 5-nm-thick In—Ga—Zn oxide as the semiconductor 663. These In—Ga—Zn oxides were deposited by DC sputtering. The atomic ratios (In:Ga:Zn) of metal elements used in sputtering targets are shown in Table 3.

TABLE 3

| | Transistor A | Transistor B |
|---|---|---|
| Semiconductor 663 | In:Ga:Zn = 1:3:2 | In:Ga:Zn = 1:3:2 |
| Semiconductor 662 | In:Ga:Zn = 1:1:1 | In:Ga:Zn = 4:2:4.1 |
| Semiconductor 661 | In:Ga:Zn = 1:3:4 | In:Ga:Zn = 1:3:4 |

A silicon wafer was used as the substrate 640 of Transistors A and B.

As the conductive films 671 and 672, a 20-nm-thick tungsten film was deposited by sputtering.

A 10-nm-thick silicon oxynitride film was deposited by plasma-enhanced CVD (PECVD) as a gate insulating film (the insulating film 653).

A stack film of a 10-nm-thick titanium nitride film and a 30-nm-thick tungsten film was deposited as a gate electrode (the conductive film 673). In the stack film, the titanium nitride film is in contact with the gate insulating film.

Note that a resist used for forming the conductive films 671 to 673 was exposed to light by an electron beam exposure system.

A 40-nm-thick aluminum oxide film was deposited by sputtering as the insulating film 654 to cover Transistors A and B, and a 150-nm-thick silicon oxynitride film was deposited by PECVD as the insulating film 655.

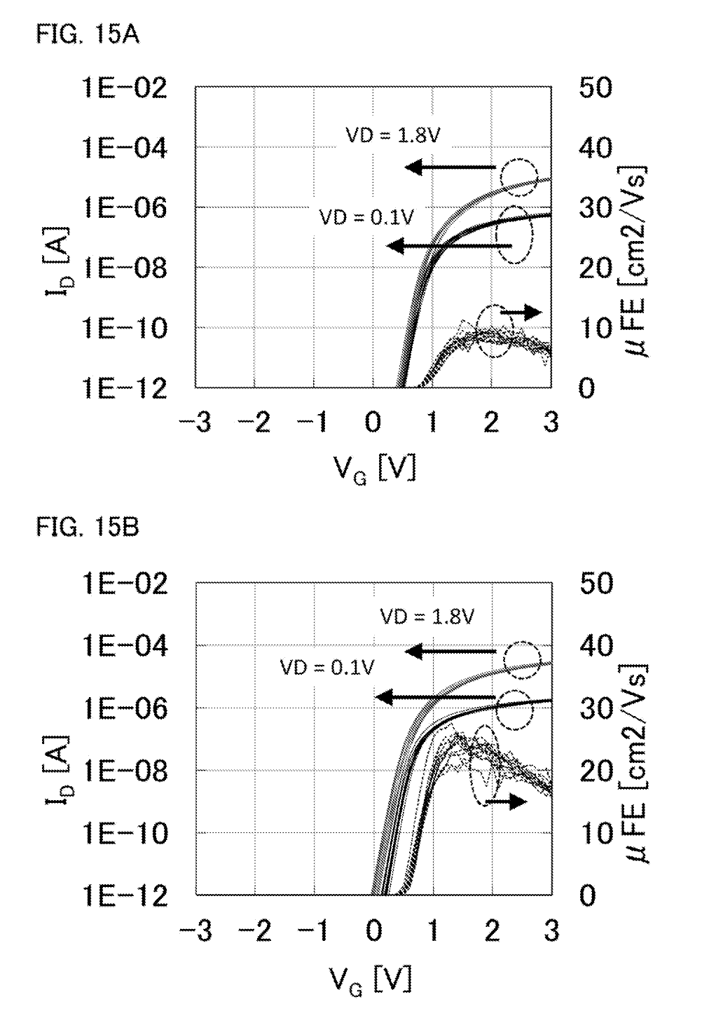

FIGS. 15A and 15B show V_{G}-I_{D} characteristics of fabricated transistors. FIG. 15A shows V_{G}-I_{D} characteristics of Transistor A, and FIG. 15B shows V_{G}-I_{D} characteristics of Transistor B. Twenty five n-channel transistors formed over one substrate were evaluated. Specifically, the transistors each designed with a channel length L of 60 nm and a channel width W of 60 nm were evaluated. The horizontal axis represents gate voltage V_{G}, the vertical axis on the left side represents drain current I_{D}, and the vertical axis on the right side represents field-effect mobility μFE. Measurement was performed at drain voltages V_{D} of 0.1 V and 1.8 V, and field-effect mobility was calculated at V_{D}=0.1 V.

FIG. 15A shows that Transistor A has an on-state current of 6.6 μA, a field-effect mobility of 9.1 cm²/Vs, a subthreshold swing of 95 mV/dec, and a threshold voltage of 0.9 V. Note that the on-state current was calculated at V_{D}=1.8 V and V_{G}=2.7 V, the field-effect mobility and the subthreshold swing were calculated at V_{D}=0.1 V, and the threshold voltage was calculated at V_{D}=1.8 V. That is, the above values are averages of measured values of the 25 transistors.

FIG. 15B shows that Transistor B has an on-state current of 22.6 μA, a field-effect mobility of 26.2 cm²/Vs, a subthreshold swing of 94 mV/dec, and a threshold voltage of 0.5 V. Note that the on-state current was calculated at V_{D}=1.8 V and V_{G}=2.7 V, the field-effect mobility and the subthreshold swing were calculated at V_{D}=0.1 V, and the threshold voltage was calculated at V_{D}=1.8 V. That is, the above values are averages of measured values of the 25 transistors.

The results in FIGS. 15A and 15B show that the transistors in one embodiment of the present invention have low threshold voltages and high field-effect mobilities.

### Example 3

In this example, the frequency characteristics of the transistors fabricated in Example 2 were evaluated. A plurality of transistors each designed with a channel length L of 60 nm and a channel width W of 60 nm were connected in parallel to measure frequency characteristics.

A network analyzer used in measurement has a standard impedance of 50Ω. When the impedance of a transistor to be measured is high, measurement accuracy is decreased in some cases. Thus, impedance was decreased by increasing the channel width of a transistor. Specifically, the channel width of the transistor was increased by connecting 300 transistors each having a channel width of 60 nm and adding up the channel widths of the plurality of transistors.

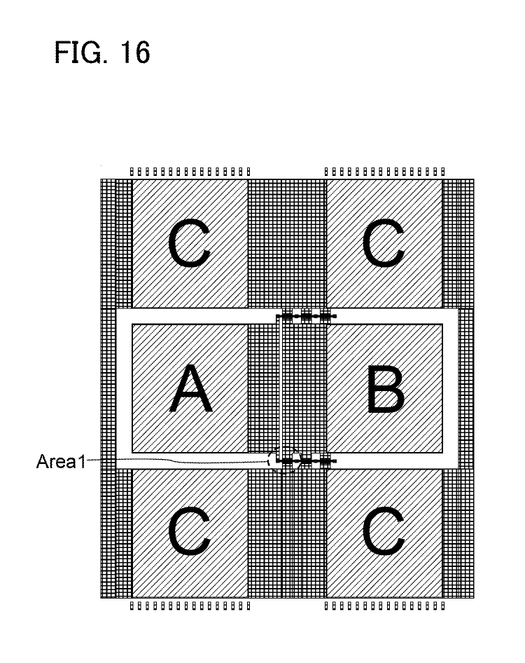

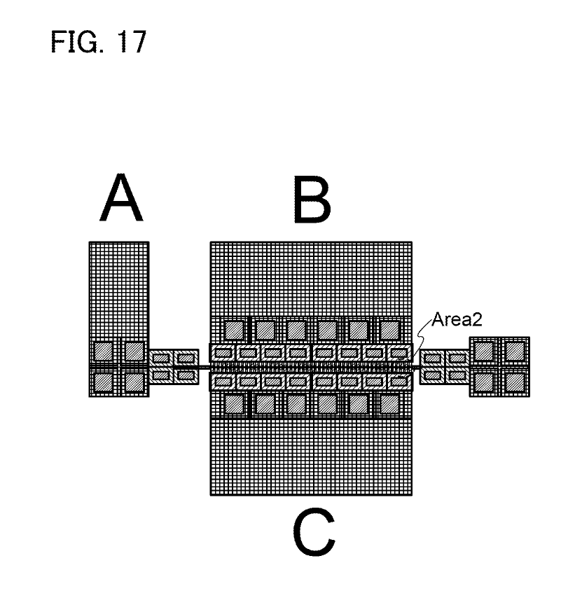

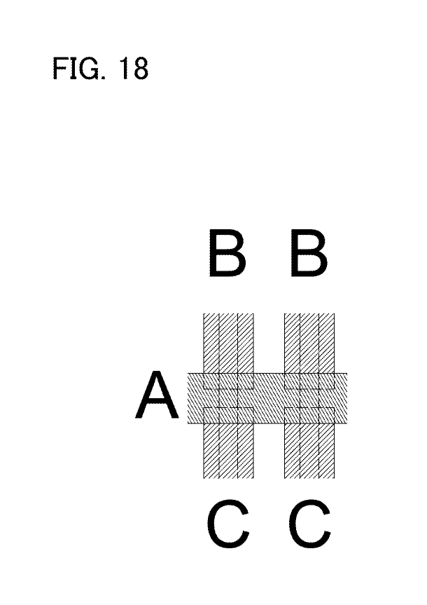

FIG. 16, FIG. 17, and FIG. 18 each show the layout of transistors to be measured.

FIG. 16 is a top view illustrating 300 transistors each having a channel width of 60 nm connected in parallel and measurement pads. A terminal A is connected to a gate of the transistor. A terminal B is connected to one of a source and a drain of the transistor. A terminal C is supplied with a GND potential and is connected to the other of the source and the drain of the transistor. Transistors are arranged in a region Area 1.

FIG. 17 is a magnified view of the region Area 1 in the top view of FIG. 16. The terminal A is connected to the gate of the transistor, and the terminals B and C are connected to the source and the drain of the transistor, respectively.

FIG. 18 is a magnified view of a region Area 2 in the top view of FIG. 17. The terminal A is connected to the gate of the transistor, and the terminals B and C are connected to the source and the drain of the transistor, respectively.

A network analyzer was used in measurement. An Agilent Technologies N5230A network analyzer and a Mini-Circuits ZX85-12G-S+ bias tee were used. In addition, ADCMT 6242 and 6241A SMUs were used.

In measurement, before a target element (device under test (DUT)) is measured, Open and Short test element groups (TEG) are measured. Accordingly, even when the DUT is embedded in an extra network, it is possible to obtain the characteristics of the DUT (this is also called de-embedding).

S parameters were measured by the network analyzer, and cutoff frequency f_{T} and maximum oscillation frequency fₘₐₓ were calculated from the S parameters. The cutoff frequency f_{T} is defined as frequency at which a current amplification factor or an extrapolated current amplification factor becomes 1. The current amplification factor is an off-diagonal component of an H matrix and is represented by the following equation using the S parameters.

$${H}_{21} = - \frac{{S}_{21}}{( 1 - {S}_{11} ) ( 1 + {S}_{22} ) + {S}_{12} {S}_{21}} \qquad ( 1 )$$

The maximum oscillation frequency fₘₐₓ is defined as frequency at which a power amplification factor or an extrapolated power amplification factor becomes 1. Maximum available power gain or maximum unilateral power gain can be used as the power amplification factor. Maximum unilateral power gain U_{g} is represented by the following equation.

$${U}_{g} = \frac{{\vert {S}_{21} \text{/} {S}_{12} - 1 \vert}^{2}}{2 K \vert {S}_{21} \text{/} {S}_{12} \vert - 2 Re ( {S}_{21} \text{/} {S}_{12} )} \qquad ( 2 )$$

In Equation (2), K is a stabilization coefficient and is represented by the following equation.

$$K = \frac{1 - {\vert {S}_{11} \vert}^{2} - {\vert {S}_{22} \vert}^{2} + {\vert {S}_{11} {S}_{22} - {S}_{12} {S}_{21} \vert}^{2}}{2 \vert {S}_{12} {S}_{21} \vert} \qquad ( 3 )$$

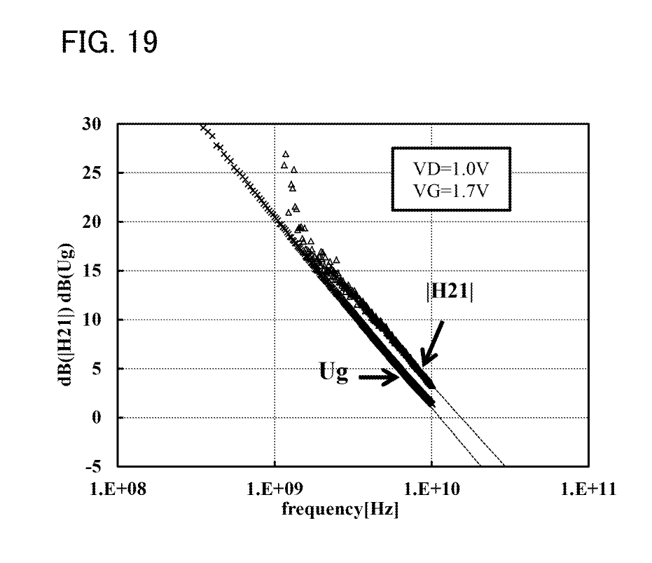

FIG. 19 shows an evaluation result example of Transistor B. Measurement was performed at V_{D}=1.0 V and V_{G}=1.7 V. An H-matrix element |H₂₁| and the maximum unilateral power gain U_{g} were calculated from measured S parameters. FIG. 19 shows data after de-emdedding. Cutoff frequency f_{T} calculated from an extrapolated value was 11.3 GHz. Similarly, maximum oscillation frequency fₘₐₓ was 15.5 GHz.

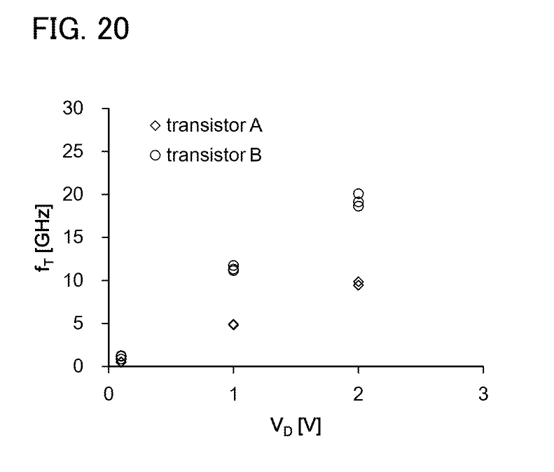

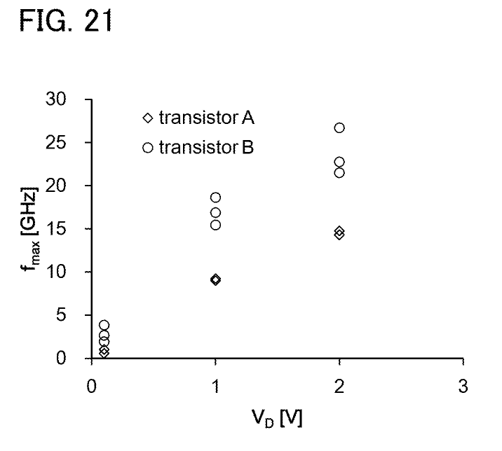

FIG. 20 and FIG. 21 show evaluation result examples of Transistor A and Transistor B. FIG. 20 shows results of cutoff frequency f_{T} calculated at V_{D}=0.1 V, 1 V, and 2 V. FIG. 21 shows results of maximum oscillation frequency fₘₐₓ calculated at V_{D}=0.1 V, 1 V, and 2 V. Note that f_{T} and fₘₐₓ were evaluated at V_{G} where transconductance gₘ has the maximum value at each V_{D}. The number of measured samples of Transistor A is two, and the number of measured samples of Transistor B is three.

From FIG. 20, average cutoff frequency f_{T} of Transistor A was 4.9 GHz at V_{D}=1.0 V and V_{G}=1.9 V, and the average cutoff frequency f_{T} of Transistor A was 9.7 GHz at V_{D}=2.0 V and V_{G}=2.35 V.

From FIG. 20, average cutoff frequency f_{T} of Transistor B was 11 GHz at V_{D}=1.0 V and V_{G}=1.7 V, and the average cutoff frequency f_{T} of Transistor B was 19 GHz at V_{D}=2.0V and V_{G}=1.95 V.

From FIG. 21, average maximum oscillation frequency fₘₐₓ of Transistor A was 9.1 GHz at V_{D}=1.0 V and V_{G}=1.9 V, and the average maximum oscillation frequency fₘₐₓ of Transistor A was 15 GHz at V_{D}=2.0 V and V_{G}=2.35 V.

From FIG. 21, average maximum oscillation frequency fₘₐₓ of Transistor B was 17 GHz at V_{D}=1.0 V and V_{G}=1.7 V, and the average maximum oscillation frequency fₘₐₓ of Transistor B was 24 GHz at V_{D}=2.0 V and V_{G}=1.95 V.

As described above, Transistor A had a cutoff frequency f_{T} of approximately 10 GHz and a maximum oscillation frequency fₘₐₓ of higher than or equal to 10 GHz at V_{D}=2.0 V. In addition, Transistor B had a cutoff frequency f_{T} of approximately 20 GHz and a maximum oscillation frequency fₘₐₓ of higher than or equal to 20 GHz. It is found that the transistor in one embodiment of the present invention has high frequency characteristics and can achieve high-speed operation when the transistor is used in a storage circuit, a logic circuit, or an analog circuit.

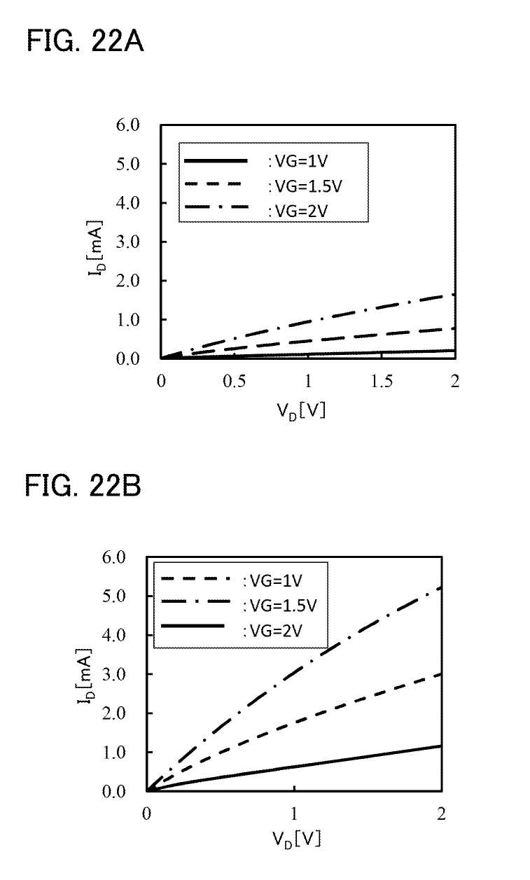

FIGS. 22A and 22B show measurement results of I_{D}-V_{D} characteristics of Transistors A and B with W/L=18 μm/60 nm. FIG. 22A shows I_{D}-V_{D} characteristics of Transistor A, and FIG. 22B shows I_{D}-V_{D} characteristics of Transistor B. Note that the I_{D}-V_{D} characteristics were measured at V_{G}=1 V, 1.5 V, and 2 V. FIGS. 22A and 22B indicate that Transistor B has higher drain current than Transistor A.

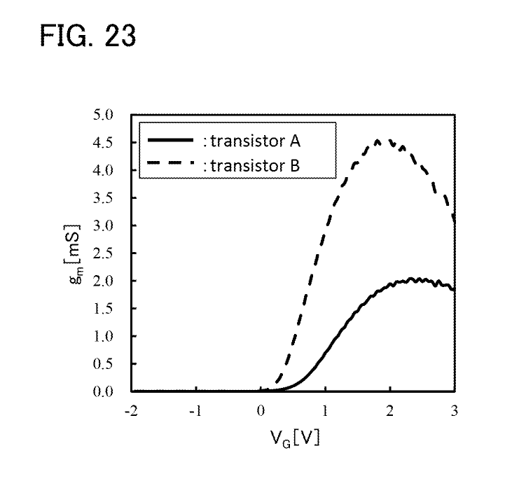

FIG. 23 shows measurement results of transconductances gₘ of Transistors A and B with W/L=18 μm/60 nm at V_{D}=2 V. FIG. 23 indicates that the peak value of the transconductance gₘ of Transistors B (gₘ=4.5 mS) is larger than that of Transistor A.

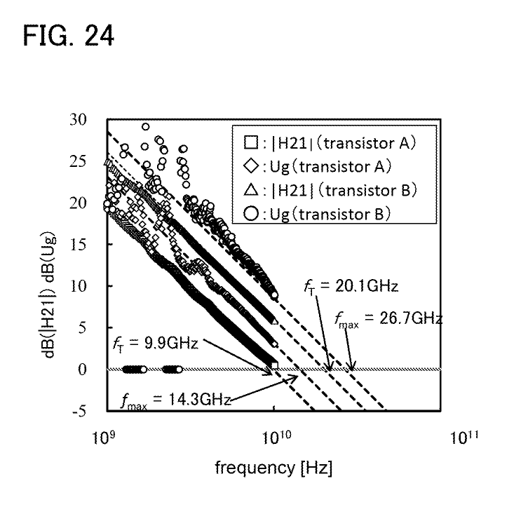

FIG. 24 shows evaluation result examples of Transistors A and B with W/L=18 μm/60 nm. Here, RF gains were measured at V_{G} where the transconductance gₘ has the maximum value at V_{D}=2 V. From FIG. 24, the cutoff frequency fᵣ of Transistor A was 9.9 GHz and the maximum oscillation frequency fₘₐₓ of Transistor A was 14.3 GHz. Furthermore, the cutoff frequency f_{T} of Transistor B was 20.1 GHz and the maximum oscillation frequency fₘₐₓ of Transistor B was 26.7 GHz. Note that FIG. 24 shows data after de-emdedding.

To obtain higher cutoff frequency f_{T}, transconductance gₘ and a breakdown of capacitance at which the cutoff frequency f_{T} is 20.1 GHz are considered.

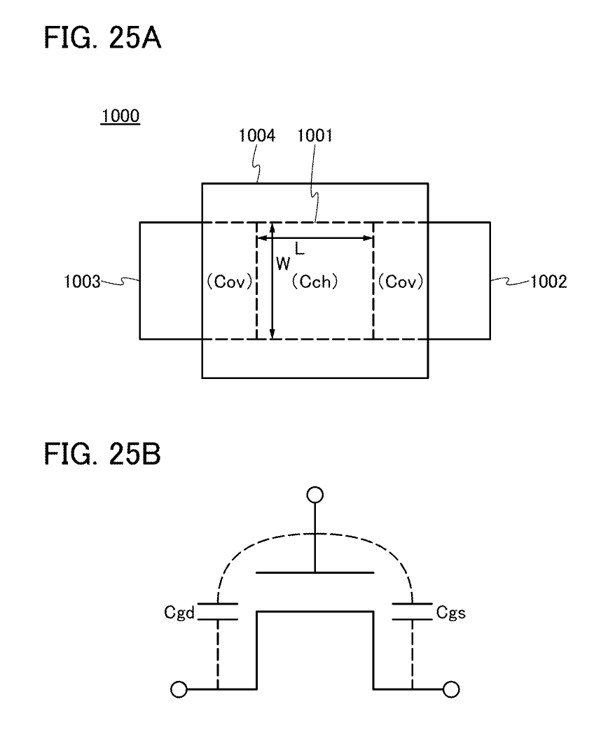

Gate-source capacitance C_{gs} and gate-drain capacitance C_{gd} of a transistor were calculated using the transconductance gₘ obtained from DC characteristics and the cutoff frequency f_{T} calculated from the S parameter. FIG. 25A shows the structure of a transistor used for evaluation in this example. A transistor 1000 includes an oxide semiconductor film 1001, a source electrode 1002, a drain electrode 1003, and a gate electrode 1004. Note that Cₒᵥ represents capacitance of a region where the gate electrode 1004 overlaps with the source electrode 1002 or the drain electrode 1003, and C_{ch} represents channel capacitance. The cutoff frequency f_{T} of the transistor 1000 is represented by the following equation.

$${f}_{T} = \frac{{g}_{m}}{2 π ( {C}_{gs} + {C}_{gd} )} \qquad ( 4 )$$

Since the transistor 1000 has a symmetrical structure, C_{gs} is equal to C_{gd} (see FIG. 25B). In addition, C_{gs} of a transistor with W/L=60 nm/60 nm is estimated at C_{gd}=C_{ch}/2+Cₒᵥ=0.059 fF. Furthermore, if C_{ch} is the capacitance of a plate capacitor, C_{ch} is estimated at W×L×Cₒᵥ=0.012 fF. Moreover, Cₒᵥ is estimated at 0.053 fF from the measurement results of the transconductance gₘ and the cutoff frequency f_{T}. Table 4 shows relationship between the transistor with W/L=18 μm/60 nm and the transistor with W/L=60 nm/60 nm.

TABLE 4

| | gₘ [mS] | f_{T} [GHz] | C_{gs}, C_{gd} [fF] |
|---|---|---|---|
| W/L = 18 μm/60 nm | 4.5 | 20.1 | 17.816 |
| W/L = 60 nm/60 nm | — | — | 0.059 |

This indicates that Cₒᵥ is dominant in C_{gs} and C_{gd} and that higher cutoff frequency f_{T} can be obtained by reducing Cₒᵥ.

This application is based on Japanese Patent Application serial No. 2014-098038 filed with Japan Patent Office on May 9, 2014 and Japanese Patent Application serial No. 2014-128281 filed with Japan Patent Office on Jun. 23, 2014, the entire contents of which are hereby incorporated by reference.

What is claimed is:

1. A transistor comprising:
a first oxide semiconductor layer;
a second oxide semiconductor layer;
a third oxide semiconductor layer;
a gate insulating layer; and
a gate electrode layer,
wherein cutoff frequency of the transistor at a source-drain voltage of higher than or equal to 1 V and lower than or equal to 2 V is higher than 1 GHz,
wherein a channel length is less than 100 nm,
wherein the second oxide semiconductor layer includes a portion between the first oxide semiconductor layer and the third oxide semiconductor layer,
wherein the gate insulating layer includes a region in contact with a top surface of the third oxide semiconductor layer,
wherein the gate electrode layer partly overlaps with the portion with the gate insulating layer positioned therebetween,
wherein the second oxide semiconductor layer includes a plurality of c-axis aligned crystal parts, and
wherein the second oxide semiconductor layer includes a region in which concentration of hydrogen measured by secondary ion mass spectrometry is lower than 2×10²⁰ atoms/cm³.

2. The transistor according to claim 1, wherein the cutoff frequency at the source-drain voltage of higher than or equal to 1 V and lower than or equal to 2 V is higher than 5 GHz.

3. The transistor according to claim 1, wherein the gate electrode layer overlaps with a top surface of the portion and a side surface of the portion in a channel width direction with the gate insulating layer positioned therebetween.

4. The transistor according to claim 1, wherein the second oxide semiconductor layer includes a region in which concentration of silicon measured by secondary ion mass spectrometry is lower than 1×10¹⁹ atoms/cm³.

5. The transistor according to claim 1, wherein the channel length is less than 65 nm.

6. The transistor according to claim 1, wherein the first to third oxide semiconductor layers contain indium, zinc, and M, where M is Al, Ti, Ga, Y, Zr, La, Ce, Nd, or Hf.

7. The transistor according to claim 6, wherein an atomic ratio of M to In in each of the first and third oxide semiconductor layers is higher than an atomic ratio of M to In in the second oxide semiconductor layer.

8. A circuit comprising an n-channel transistor and a capacitor,
wherein the capacitor is capable of being charged and discharged by drain current of the n-channel transistor, and
wherein the n-channel transistor is the transistor according to claim 1.

9. An inverter circuit comprising an n-channel transistor and a p-channel transistor, wherein the n-channel transistor is the transistor according to claim 1.

10. An electronic component comprising:
a circuit portion including one of the circuit according to claim 8 and the inverter circuit; and
a wire electrically connected to the circuit portion.

11. An electronic device comprising:
the electronic component according to claim 10; and
at least one of a microphone, a speaker, a display portion, and an operation key.

12. A transistor comprising:
a first oxide semiconductor layer;
a second oxide semiconductor layer;
a third oxide semiconductor layer;
a gate insulating layer; and
a gate electrode layer,
wherein maximum oscillation frequency of the transistor at a source-drain voltage of higher than or equal to 1 V and lower than or equal to 2 V is higher than 1 GHz,
wherein a channel length is less than 100 nm,
wherein the second oxide semiconductor layer includes a portion between the first oxide semiconductor layer and the third oxide semiconductor layer,
wherein the gate insulating layer includes a region in contact with a top surface of the third oxide semiconductor layer,
wherein the gate electrode layer partly overlaps with the portion with the gate insulating layer positioned therebetween,
wherein the second oxide semiconductor layer includes a plurality of c-axis aligned crystal parts, and
wherein the second oxide semiconductor layer includes a region in which concentration of hydrogen measured by secondary ion mass spectrometry is lower than 2×10²⁰ atoms/cm³.

13. The transistor according to claim 12, wherein the maximum oscillation frequency at the source-drain voltage of higher than or equal to 1 V and lower than or equal to 2 V is higher than 5 GHz.

14. The transistor according to claim 12, wherein the gate electrode layer overlaps with a top surface of the portion and a side surface of the portion in a channel width direction with the gate insulating layer positioned therebetween.

15. The transistor according to claim 12, wherein the second oxide semiconductor layer includes a region in which concentration of silicon measured by secondary ion mass spectrometry is lower than 1×10¹⁹ atoms/cm³.

16. The transistor according to claim 12, wherein the channel length is less than 65 nm.

17. The transistor according to claim 12, wherein the first to third oxide semiconductor layers contain indium, zinc, and M, where M is Al, Ti, Ga, Y, Zr, La, Ce, Nd, or Hf.

18. The transistor according to claim 17, wherein an atomic ratio of M to In in each of the first and third oxide semiconductor layers is higher than an atomic ratio of M to In in the second oxide semiconductor layer.

19. A circuit comprising an n-channel transistor and a capacitor,
wherein the capacitor is capable of being charged and discharged by drain current of the n-channel transistor, and
wherein the n-channel transistor is the transistor according to claim 12.

20. An inverter circuit comprising an n-channel transistor and a p-channel transistor, wherein the n-channel transistor is the transistor according to claim 12.

21. An electronic component comprising:
a circuit portion including one of the circuit according to claim 19 and the inverter circuit; and
a wire electrically connected to the circuit portion.

22. An electronic device comprising:
the electronic component according to claim 21; and
at least one of a microphone, a speaker, a display portion, and an operation key.
